(19) United States
(12) Patent Application Publication
(10) Pub. No.: US 2025/0279069 A1
(43) Pub. Date: Sep. 4, 2025

(54) DISPLAY DEVICE AND ELECTRONIC APPARATUS

(71) Applicant: Samsung Display Co., Ltd., Yongin-si (KR)

(72) Inventor: SANGHYUN LIM, Yongin-si (KR)

(21) Appl. No.: 19/029,061

(22) Filed: Jan. 17, 2025

(30) Foreign Application Priority Data
Feb. 29, 2024 (KR) 10-2024-0029924

(51) Int. Cl. G09G 3/3275

(52) U.S. Cl. CPC G09G 3/3275; G09G 2310/0297; G09G 2330/021

(57) ABSTRACT

A display device includes a display panel including first and second data lines and one or more pixels including a first pixel and a second pixel, a light control layer above the display panel, including a light-blocking part, and configured to control light emitted from the one or more pixels, a demultiplexer circuit electrically connected to the display panel, and including a first switch connected to the first data line, and a second switch connected to the second data line, and a data-driving circuit connected to the demultiplexer circuit, and configured to provide a data signal including a first data signal including a first voltage level to the first data line based on activation of the first switch, and a second data signal including a second voltage level that is different from the first voltage level to the second data line based on activation of the second switch.

### CROSS-REFERENCE TO RELATED APPLICATION

The present application claims priority to and the benefit of Korean Patent Application No. 10-2024-0029924, filed on Feb. 29, 2024, in the Korean Intellectual Property Office, the entire disclosure of which is incorporated herein by reference.

### BACKGROUND

The present disclosure herein relates to a display device that may have reduced power consumption and improved (and/or suitable) display quality and sensing reliability and an electronic apparatus that may include the display device.

Multimedia electronic apparatuses such as televisions, mobile phones, tablet computers, navigation devices, and game consoles may include a display device for displaying an image. The display device may include an organic light-emitting display device. The organic light-emitting display device may include a light-emitting element, and the light-emitting element may generate light through re-combination of electrons and holes. An organic light-emitting electronic apparatus may have higher response speed and may be driven with lower power consumption.

### SUMMARY

The present disclosure provides a display device that may have reduced power consumption and improved (and/or suitable) display quality and sensing reliability and an electronic apparatus that may include the display device.

One or more embodiments of the present disclosure provides a display device including a display panel configured to operate in one or more frames, and including a first data line, a second data line, and one or more pixels including a first pixel including a first light-emitting element and a first pixel circuit connected to the first data line, and a second pixel including a second light-emitting element and a second pixel circuit connected to the second data line, a light control layer above the display panel, including a light-blocking part, and configured to control light emitted from the one or more pixels, a demultiplexer circuit electrically connected to the display panel, and including a first switch connected to the first data line, and a second switch connected to the second data line, and a data-driving circuit connected to the demultiplexer circuit, and configured to provide a data signal including a first data signal including a first voltage level to the first data line based on activation of the first switch, and a second data signal including a second voltage level that is different from the first voltage level to the second data line based on activation of the second switch.

The first light-emitting element may include a first emission layer, and the second light-emitting element includes a second emission layer, wherein the light-blocking part surrounds the first emission layer and the second emission layer in plan view, and defines a first opening overlapping the first emission layer and a second opening overlapping the second emission layer.

The display panel may further include a third data line and a fourth data line, wherein the one or more pixels include one or more third pixels including a third pixel circuit and a third light-emitting element, and wherein the one or more third pixels includes a fourth pixel electrically connected to the third data line, and a fifth pixel electrically connected to the fourth data line.

The third light-emitting element may include a third emission layer, wherein the light-blocking part surrounds the third emission layer of the fourth pixel, and does not overlap the third emission layer of the fifth pixel, in plan view, wherein the light-blocking part defines a third opening overlaps the third emission layer of the fourth pixel.

The data signal may further include a third data signal and a fourth data signal, wherein the demultiplexer circuit further includes a third switch connected to the third data line and the data-driving circuit and a fourth switch connected to the fourth data line and the data-driving circuit.

The data-driving circuit may be configured to provide the third data signal to the third data line based on activation of the third switch.

The third data signal may correspond to black being displayed in the third light-emitting element.

The data-driving circuit may be configured to provide the fourth data signal to the fourth data line based on activation of the fourth switch.

The fourth data signal may include a third voltage level that is different from the first voltage level and the second voltage level.

The first light-emitting element may include a first emission layer, wherein the second light-emitting element includes a second emission layer, wherein the light-blocking part includes a first light-blocking portion surrounding the first emission layer, and spaced from an edge of the first emission layer by a first width, in plan view, and a second light-blocking portion surrounding the second emission layer, and spaced from an edge of the second emission layer by a second width, in plan view, the second width being less than the first width.

The first light-blocking portion and the second light-blocking portion may be integral.

The light-blocking part may cover a surface of the display panel, and may define first openings overlapping the first light-emitting element and the second light-emitting element in a plan view, and second openings that are smaller than the first openings.

The display device may further include a black signal provider circuit configured to provide a black signal to the one or more third pixels, and including a black switch configured to control the black signal, wherein the display panel is configured to operate in a first mode or in a second mode different from the first mode.

The black signal provider circuit may be configured to provide the black signal to the third data line based on activation of the black switch in the first mode.

The data-driving circuit may be configured to provide the fourth data signal to the third data line based on activation of a normal switch in the second mode.

One or more embodiments of the present disclosure may provide an electronic apparatus including a display panel configured to operate in one or more frames and including a first pixel and a second pixel, a light control layer arranged on the display panel and including a light-blocking part, a data-driving circuit configured to provide a data signal to the display panel, and a demultiplexer circuit electrically connected to the data-driving circuit and the display panel, wherein the light-blocking part is configured to control light emitted from the first pixel and the second pixel, wherein the data signal including a first data signal including a first voltage level and a second data signal including a second voltage level different from the first voltage level, and wherein the demultiplexer circuit configured to transfer the first data signal to the first pixel, and transfer the second data signal to the second pixel.

The first pixel may be configured to receive the data signal based on the one or more frames, wherein the second pixel is configured to receive the data signal based on the one or more frames.

The first pixel may include a first emission layer, and the second pixel includes a second emission layer, the light blocking part surrounds each of the first emission layer and the second emission layer in a plan view, and the light blocking part defines an opening overlapping each of the first emission layer and the second emission layer.

The display panel may further include one or more third pixels, wherein the one or more third pixels a include a fourth pixel and a fifth pixel.

The one or more third pixels may include a third emission layer wherein the light-blocking part further surrounds the third emission layer of the fourth pixel, and does not overlap the third emission layer of the fourth pixel, in a plan view, wherein the opening further overlaps the third emission layer of the fourth pixel.

The data signal may further include a third data signal and a fourth data signal, wherein the fourth data signal is based on black displayed in the third emission layer.

The fourth data signal may include a third voltage level different from the first voltage level and the second voltage level.

The first pixel may include a first emission layer, and the second pixel includes a second emission layer, wherein the light-blocking part includes a first light-blocking portion and a second light-blocking portion, wherein the first light-blocking portion surrounds the first emission layer, and wherein the second light-blocking portion surrounds the second emission layer.

The first light-blocking portion and the second light-blocking portion may be configured to a defined shape.

The electronic apparatus may further include one or more of the first pixel, wherein the light-blocking part is configured to cover a surface of the display panel and includes one or more openings.

The electronic apparatus may further include a black signal provider circuit configured to provide a black signal to the fourth pixel, and including a black switch configured to control the black signal, wherein the display panel is configured to operate in a first mode, or in a second mode different from the first mode.

The black signal provider circuit may be configured to provide the black signal to the fourth pixel.

### BRIEF DESCRIPTION OF THE DRAWINGS

The accompanying drawings are included to provide a further understanding of the present disclosure, and are incorporated in and constitute a part of this specification. The drawings illustrate one or more embodiments of the present disclosure and, together with the description, describe aspects of the present disclosure.

FIG. 1 depicts a perspective view of an example of an electronic apparatus according to one or more embodiments of the present disclosure.

FIG. 2 depicts a perspective view of another example of an electronic apparatus according to one or more embodiments of the present disclosure.

FIG. 3 depicts a perspective view of another example of an electronic apparatus according to one or more embodiments of the present disclosure.

FIG. 4 depicts a block diagram of a display device according to one or more embodiments of the present disclosure.

FIG. 5 depicts a circuit diagram of a pixel according to one or more embodiments of the present disclosure.

FIG. 6 depicts a cross-sectional view illustrating a portion of a display device according to one or more embodiments of the present disclosure.

FIG. 7 depicts a plan view illustrating a portion of a display device according to one or more embodiments of the present disclosure.

FIG. 8A depicts a diagram illustrating a first mode and a second mode of a display panel according to one or more embodiments of the present disclosure.

FIG. 8B depicts a graph of a first line control signal and a second line control signal according to one or more embodiments of the present disclosure.

FIG. 8C depicts a graph of a voltage level of a data signal according to one or more embodiments of the present disclosure.

FIG. 9A depicts a plan view showing an arrangement of a light-blocking portion according to one or more embodiments of the present disclosure.

FIG. 9B depicts a plan view showing an arrangement of a light-blocking portion according to one or more embodiments of the present disclosure.

FIG. 9C depicts a plan view showing an arrangement of a light-blocking portion according to one or more embodiments of the present disclosure.

FIG. 10 depicts a plan view illustrating a portion of a display device according to one or more embodiments of the present disclosure.

FIG. 11 depicts a diagram illustrating a first mode and a second mode according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In one or more embodiments, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments are described in detail with reference to the accompanying drawings so that those skilled in the art may easily practice the disclosure. The disclosure may be implemented in one or more suitable different forms and is not limited to the example embodiments described in the specification.

A part irrelevant to the description may not be provided to clearly describe the disclosure, and the same or similar constituent elements may be designated by the same reference numerals throughout the specification. Therefore, the same reference numerals may be utilized in different drawings to identify the same or similar elements.

In one or more embodiments, the expression “the same” in the description may refer to “substantially the same.” For example, it may be the same to the extent that a person with ordinary knowledge can understand that it is the same. Other expressions may also be expressions in which “substantially” is not provided.

Hereinafter, one or more embodiments of the present disclosure will be described with reference to the accompanying drawings.

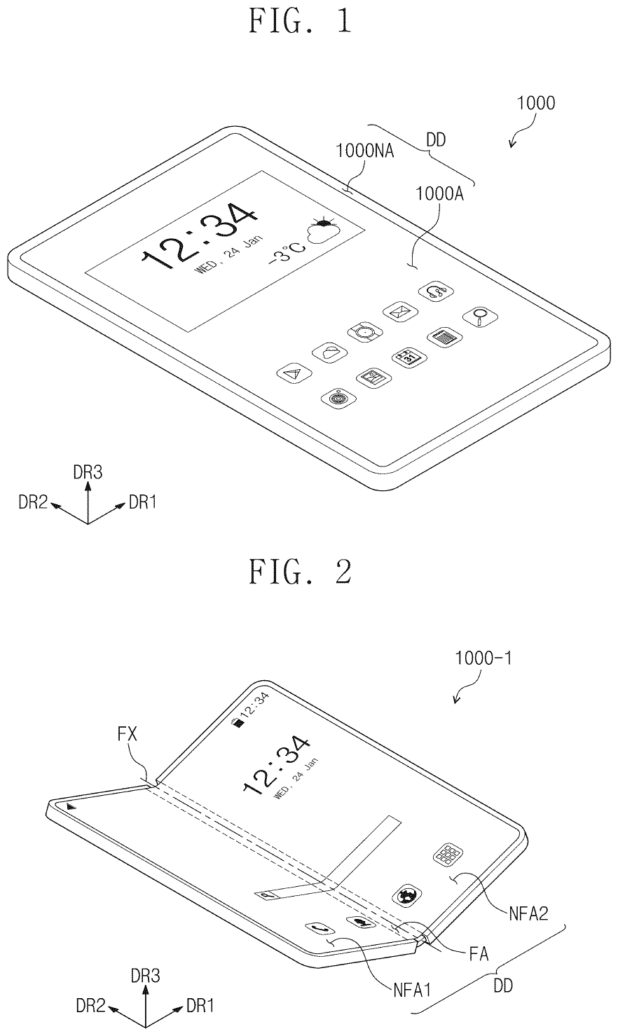

FIG. 1 depicts a perspective view of an example of an electronic apparatus 1000 according to one or more embodiments of the present disclosure.

FIG. 1 illustrates that an electronic apparatus 1000 may be a mobile phone. The electronic apparatus 1000 may include a display device DD. An active region 1000A and a peripheral region 1000NA may be provided (e.g., defined) in the display device DD. The display device DD may display an image through the active region 1000A. The active region 1000A may include a plane defined by a first direction DR1 and a second direction DR2 (e.g., horizontal axis). The peripheral region 1000NA may surround the active region 1000A. In one or more embodiments of the present disclosure, the electronic apparatus 1000 may include the active region 1000A and the peripheral region 1000NA may not be provided.

A height or thickness direction of the electronic apparatus 1000 and/or the display device DD may be parallel to a third direction DR3 (e.g., vertical axis) that is normal (e.g., perpendicular) to the first direction DR1 and the second direction DR2. Thus, front surfaces (and/or upper surfaces) and rear surfaces (and/or lower surfaces) of elements included in the electronic apparatus 1000 and/or the display device DD may be referred to with respect to the third direction DR3.

The electronic apparatus 1000 according to one or more embodiments may be a device that displays a moving image and/or a still image. The electronic apparatus 1000 may be applied to portable electronic devices such as mobile phones, smartphones, tablet personal computers (PCs), mobile communication terminals, electronic notebooks, electronic books, portable multimedia players (PMPs), navigations, and ultra-mobile PCs (UMPCs). For example, the electronic apparatus 1000 may be applied to a display unit of a television, a laptop computer, a monitor, a billboard, or the Internet of Things (IoT). Alternatively, in one or more embodiments, the electronic apparatus 1000 may be applied to a smartwatch, a watch phone, a virtual reality (VR) device, an augmented reality (AR) device, and/or a head-mounted display device (HMD) (e.g., for implementing virtual reality and/or augmented reality).

FIG. 2 depicts a perspective view of another example of an electronic apparatus 1000-1 according to one or more embodiments of the present disclosure.

Referring to FIG. 2, an electronic apparatus 1000-1 may include a display device DD. The display device DD may include a folding region FA and one or more non-folding (e.g., rigid) regions, depicted in FIG. 2 as NFA1 and NFA2. The non-folding region NFA1 may be referred to as a first non-folding region and non-folding region NFA2 may be referred to as a second non-folding region. The folding region FA may be arranged between the first non-folding region NFA1 and the second non-folding region NFA2. The folding region FA may also be referred to as a foldable region, the first non-folding region NFA1 may also be referred to as a first non-foldable region, and the second non-folding region NFA2 may also be referred to as a second non-foldable region.

As illustrated in FIG. 2, the folding region FA may be folded with respect to a folding axis FX parallel to a second direction DR2 (e.g., horizontal axis). The folding region FA may have a provided (e.g., predetermined) curvature and/or a curvature radius in a folded state of the electronic apparatus 1000-1. The electronic apparatus 1000-1 may be inner-folded so that the upper surface of the first non-folding region NFA1 and the upper surface of the second non-folding region NFA2 substantially come in to contact (e.g., face each other) so that the upper surface (e.g., display surface) of the display device DD is positioned inward and/or not exposed to the outside.

In one or more embodiments of the present disclosure, the electronic apparatus 1000-1 may be outer-folded so that the upper surface (e.g., display surface) of the display device DD is positioned outwardly and/or exposed to the outside. In one or more embodiments of the present disclosure, the electronic apparatus 1000-1 may be inner-folded and/or outer-folded in an unfolded state, but embodiments of the present disclosure are not limited thereto.

FIG. 2 illustrates that one folding axis FX may be provided (e.g., defined) in the electronic apparatus 1000-1 as an example, but embodiments of the present disclosure are not limited thereto. For example, one or more folding axes may be provided in the electronic apparatus 1000-1, and the electronic apparatus 1000-1 may be inner-folded and/or outer-folded in an unfolded state at each of the one or more folding axes.

The monolithic (e.g., bar, rigid, non-foldable, etc.) electronic apparatus 1000 and the foldable electronic apparatus 1000-1 may be examples described with reference to FIGS. 1 and 2 respectively, but embodiments of the present disclosure are not limited thereto. For example, descriptions below may be applied to one or more suitable electronic apparatuses such as a curved electronic apparatus, a rollable electronic apparatus, a slidable electronic apparatus, and/or the like.

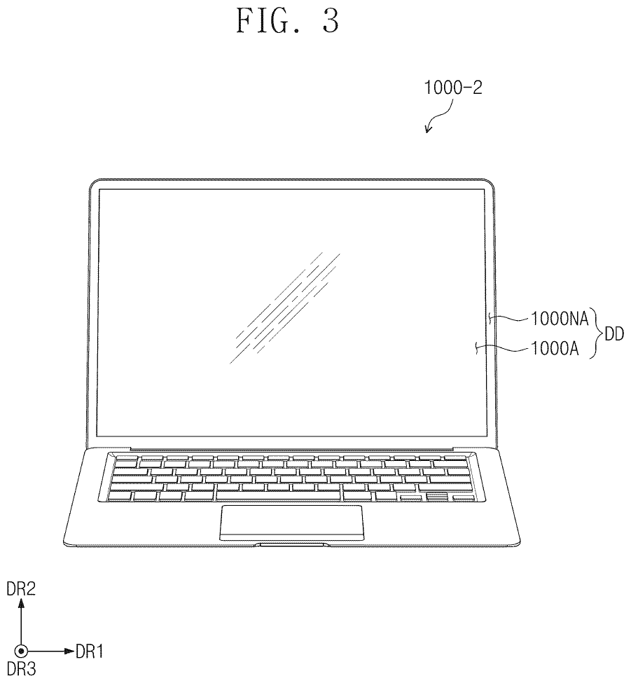

FIG. 3 depicts a perspective view of another example of an electronic apparatus 1000-2 according to one or more embodiments of the present disclosure.

FIG. 3 illustrates that an electronic apparatus 1000-2 may be a laptop. The electronic apparatus 1000-2 may include a display device DD. An active region 1000A and a peripheral region 1000NA may be provided (e.g., defined) in the display device DD. The display device DD may display an image through the active region 1000A.

As described with reference to FIGS. 1 to 3, one or more of the electronic apparatuses 1000, 1000-1, and 1000-2 may be activated in response to an electrical signal. For example, one or more of the electronic apparatuses 1000, 1000-1, and 1000-2 may be a mobile phone, a foldable mobile phone, a laptop, a television, a tablet PC, a car navigation device, a game console, or a wearable device, and/or the like, but the embodiments of the present disclosure are not limited thereto. In one or more embodiments, the wearable device may be a device which is worn on a user's body and may include a type (or kind) of display such as a head mounted display (HMD) which may provide virtual technologies such as extended reality (XR), for example.

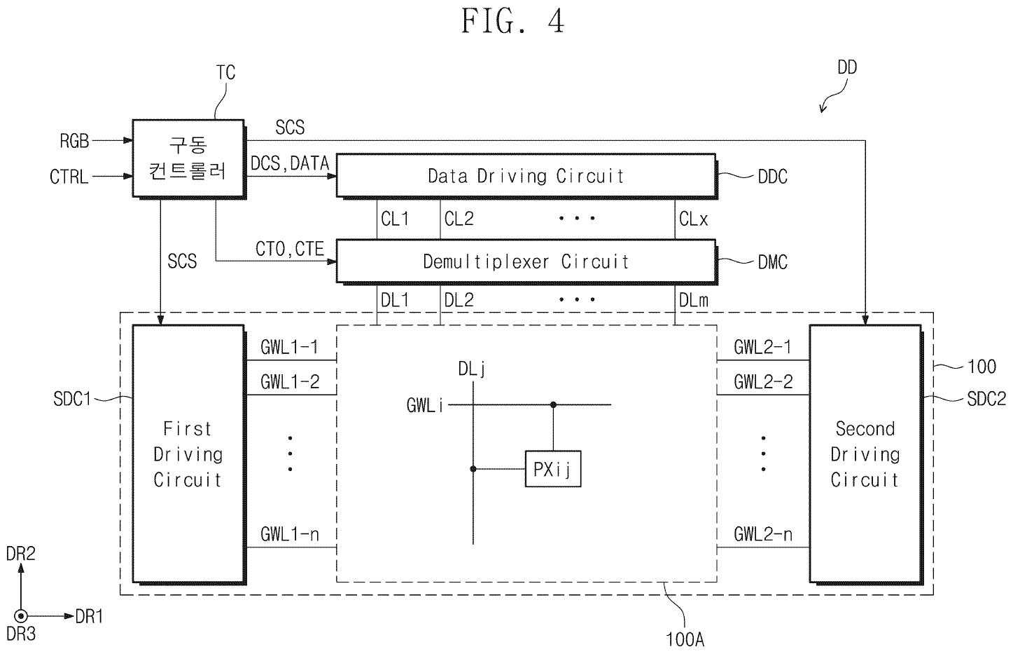

FIG. 4 depicts a block diagram of a display device DD according to one or more embodiments of the present disclosure.

Referring to FIG. 4, a display device DD may include a driving controller TC, a data-driving circuit DDC, a demultiplexer circuit DMC, a first driving circuit SDC1, a second driving circuit SDC2, and a display panel 100. An active region 100A may be provided (e.g., defined) in the display panel 100. In a plan view, the active region 100A may overlap the active region 1000A (see FIG. 1) of the display device DD (see FIG. 1).

In one or more embodiments of the present disclosure, the first driving circuit SDC1, the second driving circuit SDC2, and a pixel PXij arranged in the active region 100A may be components included in the display panel 100. The driving controller TC and the data-driving circuit DDC may each be implemented as an integrated circuit (IC) and mounted in a provided (e.g., predetermined) region of the display panel 100 and/or mounted on a separate printed circuit board utilizing a chip-on-film (COF) method and electrically connected to the display panel 100.

The display panel 100 may include a non-emissive display panel and/or an emissive display panel. The non-emissive display panel may include a liquid crystal display panel. The emissive display panel may include an organic light-emitting display (LED) panel, a quantum dot light-emitting display panel, a micro-LED display panel, and/or a nano-LED display panel. An emission layer of the organic light-emitting display panel may include an organic light-emitting material. An emission layer of the quantum dot light-emitting display panel may include a quantum dot and/or a quantum rod. An emission layer of the micro-LED display panel may include a micro-LED. An emission layer of the nano-LED display panel may include a nano-LED. In one or more embodiments, the display panel 100 may be described as including an organic light-emitting display panel.

The display panel 100 may include first gate lines GWL₁₋₁ to GWL₁₋ₙ, second gate lines GWL₂₋₁ to GWL₂₋ₙ, and data lines DL₁ to DLₘ. The data lines DL₁ to DLₘ may be arranged along a first direction DR1, the first gate lines GWL₁₋₁ to GWL₁₋ₙ may be arranged along a second direction DR2 crossing the first direction DR1, and the second gate lines GWL₂₋₁ to GWL₂₋ₙ may be arranged along the second direction DR2. The first gate lines GWL₁₋₁ to GWL₁₋ₙ and the second gate lines GWL₂₋₁ to GWL₂₋ₙ may be referred to as first write scan lines GWL₁₋₁ to GWL₁₋ₙ and second write scan lines GWL₂₋₁ to GWL₂₋ₙ.

In one or more embodiments, the display panel 100 may include one or more pixels connected to the first gate lines GWL₁₋₁ to GWL₁₋ₙ, the second gate lines GWL₂₋₁ to GWL₂₋ₙ, and the data lines DL₁ to DLₘ. FIG. 4 illustrates an example of a pixel PXij that may represent multiple pixels. The one pixel PXij may be electrically connected to one gate line GWLᵢ among the first gate lines GWL₁₋₁ to GWL₁₋ₙ and the second gate lines GWL₂₋₁ to GWL₂₋ₙ and one data line DLⱼ among the data lines DL₁ to DLₘ (where m and n are integers greater than 1).

In one or more embodiments of the present disclosure, signal lines connected to the pixel PXij may be set in a manner that is suitable according to a circuit structure of the pixel PXij. Thus, FIG. 4 illustrates at least one gate line and at least one data line as an example, and the pixel PXij may be electrically connected to other lines in addition to the lines illustrated in FIG. 4.

The driving controller TC may receive an image signal RGB and a control signal CTRL. The driving controller TC may generate an image data signal DATA by converting a data format of the image signal RGB to comply with specifications to interface with the data-driving circuit DDC. The driving controller TC may generate a first control signal DCS for controlling the data-driving circuit DDC and a second control signal SCS for controlling the first and second driving circuits SDC1 and SDC2. The driving controller TC may generate the first and second line control signals CTO and CTE for controlling the demultiplexer circuit DMC.

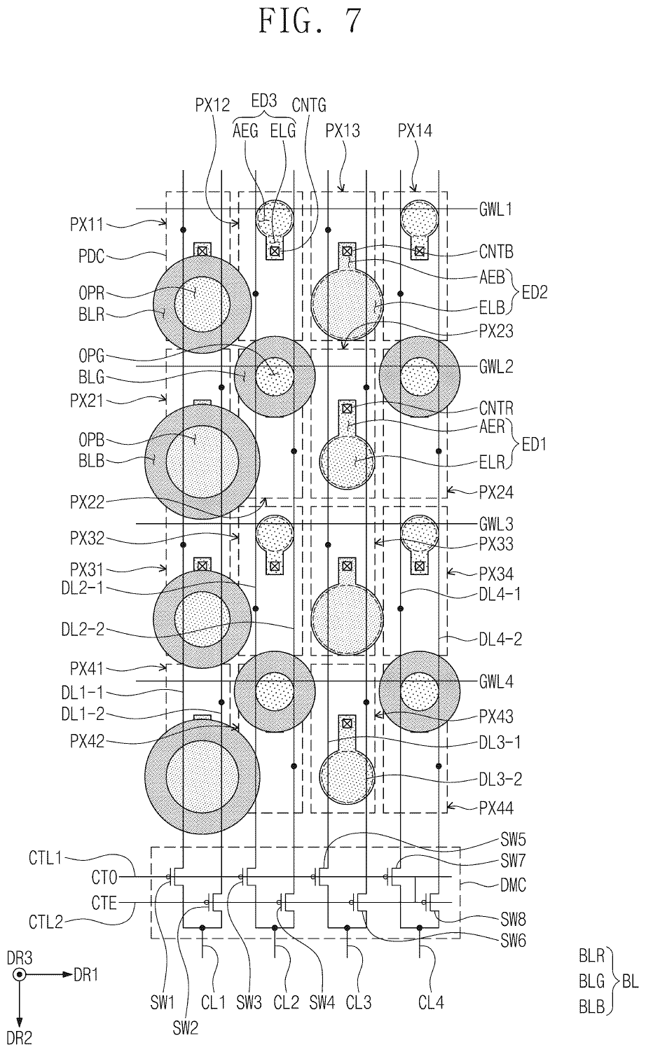

The demultiplexer circuit DMC may be a component electrically connected between the data-driving circuit DDC and the display panel 100. In one or more embodiments of the present disclosure, the display device DD may further include channel lines CL₁ to CLₓ. The channel lines CL₁ to CLₓ may be selected to be electrically connected to the data lines DL₁ to DLₘ through the demultiplexer circuit DMC. The number of the channel lines CL₁ to CLₓ may be fewer (e.g., less) than the number of the data lines DL₁ to DLₘ. In one or more embodiments of the present disclosure, a first channel line CL₁ may be electrically connected to a first data line DL₁. The first data line DL₁ may include a (1-1)-th data line DL₁₋₁ (see FIG. 7) (also referred to as a first data line) and a (1-2)-th data line DL₁₋₂ (see FIG. 7) (also referred to as a second data line). The first channel line CL₁ may be selected to be connected to the (1-1)-th data line DL₁₋₁ (see FIG. 7) and/or the (1-2)-th data line DL₁₋₂ (see FIG. 7) based on the the first and second line control signals CTO and CTE.

In one or more embodiments, in reference to FIG. 4, the demultiplexer circuit DMC may be implemented as a separate integrated circuit, but embodiments of the present disclosure are not limited thereto. For example, the demultiplexer circuit DMC may be included in the data-driving circuit DDC, included in the display panel 100, and/or integrated in a printed circuit board on which the data-driving circuit DDC is mounted (where x is an integer greater than 1 and less than m).

In one or more embodiments of the present disclosure, the number of channels of data that are output from the data-driving circuit DDC may be fewer (e.g., less) than the number of the data lines DL₁ to DLₘ due to the demultiplexer circuit DMC. The number of the channels may correspond to the number of the channel lines CL₁ to CLₓ. In one or more embodiments, the number of IC chips including a data-driving circuit DDC that may be included in a medium-sized and/or a large-sized electronic apparatus 1000-2 as in FIG. 3 may be decreased according to a decrease in the number of channels. In one or more embodiments, the number of channels of a single IC chip including the data-driving circuit DDC may be decreased, and thus cost of the IC chip may be reduced.

The data-driving circuit DDC may receive the first control signal DCS and/or the image data signal DATA from the driving controller TC. The data-driving circuit DDC may convert the image data signal DATA into data signals, and may output the data signals to the channel lines CL₁ to CLₓ. The data signals may be analog voltages corresponding to gray scale values of the image data signal DATA. The demultiplexer circuit DMC may electrically connect one or more data lines among the data lines DL₁ to DLₘ to the channel lines CL₁ to CLₓ, and the data signal may be output to the one or more data lines.

The first driving circuit SDC1 may be connected to the first gate lines GWL₁₋₁ to GWL₁₋ₙ, and the second driving circuit SDC2 may be connected to the second gate lines GWL₂₋₁ to GWL₂₋ₙ. The first driving circuit SDC1 and/or the second driving circuit SDC2 may each receive the second control signal SCS from the driving controller TC and may respectively supply a scan signal to the first gate lines GWL₁₋₁ to GWL₁₋ₙ and the second gate lines GWL₂₋₁ to GWL₂₋ₙ based on the second control signal SCS.

The scan signal may be set to a voltage at which transistors supplied with the scan signal may be turned on. For example, a scan signal which is supplied to a P-type transistor may be set to a logic low (e.g., relatively low) level, and a scan signal which is supplied to an N-type transistor may be set to a logic high (e.g., relatively high) level. Hereinafter, it may be understood that the wording “a scan signal is supplied” or “a scan signal is activated” may refer to a scan signal at a logic level that turns on a transistor controlled by the scan signal.

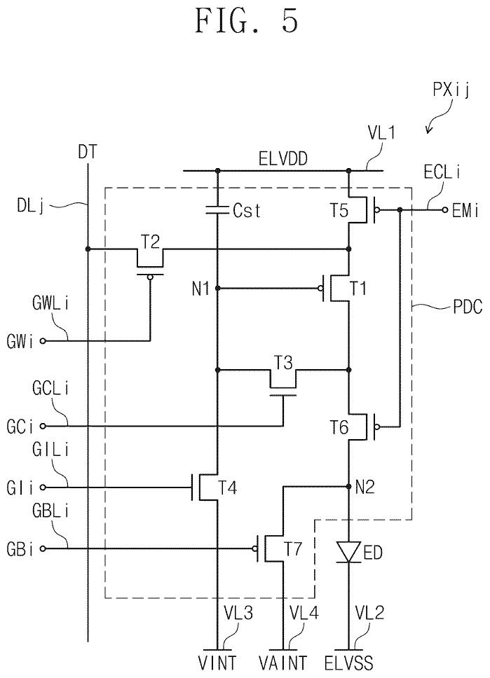

In one or more embodiments of the present disclosure, the first driving circuit SDC1 and/or the second driving circuit SDC2 may be included in the display panel 100. For example, the pixel PXij may include a light-emitting element ED (see FIG. 5) and a pixel-driving circuit PDC (see FIG. 5) which may control light emission of the light-emitting element ED. The pixel-driving circuit PDC may include one or more transistors and/or one or more capacitors. The first driving circuit SDC1 and/or the second driving circuit SDC2 may include transistors which are formed (or provided) through a substantially similar and/or suitable process that is utilized for the pixel-driving circuit PDC.

In one or more embodiments of the present disclosure, the first driving circuit SDC1 and/or the second driving circuit SDC2 may be substantially separated (e.g., spaced apart) from each other with the active region 100A therebetween. However, embodiments of the present disclosure are not limited thereto. For example, the first driving circuit SDC1 and the second driving circuit SDC2 may be arranged on the same side of the active region 100A, or at least a portion of the first driving circuit SDC1 and the second driving circuit SDC2 may be arranged in the active region 100A.

FIG. 5 depicts an equivalent circuit diagram of a pixel PXij according to one or more embodiments of the present disclosure.

Referring to FIG. 5, a pixel PXij may include a light-emitting element ED and a pixel-driving circuit PDC. The light-emitting element ED may be a light-emitting diode. As an example, the light-emitting element ED may be an organic light-emitting diode including an organic emission layer, but embodiments of the present disclosure are not limited thereto. The pixel-driving circuit PDC may control the amount of current flowing through the light-emitting element ED according to a data signal DT. The light-emitting element ED may be to emit light having a provided (e.g., predetermined) luminance according to the amount of current provided from the pixel-driving circuit PDC.

The pixel-driving circuit PDC may include first to seventh transistors T1, T2, T3, T4, T5, T6, and T7, and one capacitor Cst. In one or more embodiments, the configuration of the pixel-driving circuit PDC may not be limited to the example illustrated in FIG. 5. The pixel-driving circuit PDC illustrated in FIG. 5 is an example, and thus the configuration of the pixel-driving circuit PDC may be implemented as suitable. For example, the number of transistors and/or the number of capacitors included in the pixel-driving circuit PDC are not limited to the example illustrated in FIG. 5.

One or more of (e.g., at least one selected) the first to seventh transistors T1 to T7 may be a transistor having a relatively low-temperature polycrystalline silicon (LTPS) semiconductor layer. One or more of (e.g., at least one selected) the first to seventh transistors T1 to T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

In one or more embodiments, the first transistor T1, which may affect brightness of the light-emitting element ED, may include a semiconductor layer including polycrystalline silicon having relatively high (or increased) reliability, and a display device having relatively high resolution may thus be implemented. In one or more embodiments, because an oxide semiconductor has substantially high (or increased) carrier mobility and substantially low (or decreased) leakage current, a voltage drop may not be significant (e.g., big) even if driving time is relatively long. For example, color change of an image according to a voltage drop may not be substantial even during relatively low frequency driving, and thus low frequency driving may be possible. As described above, because an oxide semiconductor may have a relatively small leakage current, at least one of the third transistor T3 connected to a gate electrode of the first transistor T1 and/or the fourth transistor T4 may be employed as an oxide semiconductor to reduce power consumption while preventing or reducing the leakage current which may flow to the gate electrode.

One or more of the first to seventh transistors T1, T2, T3, T4, T5, T6, and T7 may be a P-type transistor, and one or more of the remaining transistors may be an N-type transistor. For example, the first, second, fifth, sixth, and/or seventh transistors T1, T2, T5, T6, and T7 may be P-type transistors, and the third and/or fourth transistors T3 and T4 may be N-type transistors.

In one or more embodiments, the configuration of the pixel-driving circuit PDC may not be limited to the example illustrated in FIG. 5. The pixel-driving circuit PDC is illustrated in FIG. 5 is an example, and the configuration of the pixel-driving circuit PDC may be implemented as suitable. For example, the first to seventh transistors T1, T2, T3, T4, T5, T6, and T7 may be P-type transistors or N-type transistors. Alternatively, the first, second, fifth, and sixth transistors T1, T2, T5, and/or T6 may be P-type transistors, and the third, fourth, and seventh transistors T3, T4, and/or T7 may be N-type transistors.

An i-th initialization scan line GILᵢ, an i-th compensation scan line GCLᵢ, an i-th gate line GWLᵢ, an i-th black scan line GBLᵢ, and an i-th emission control line ECLᵢ may respectively transfer an i-th initialization scan signal Glᵢ, an i-th compensation scan signal GCᵢ, an i-th write scan signal GWᵢ, an i-th black scan signal GBᵢ, and an i-th emission control signal EMᵢ to the pixel PXij. A j-th data line DLⱼ may transfer the data signal DT to the pixel PXij. The data signal DT may have a voltage level corresponding to an image signal.

First and second driving voltage lines VL1 and VL2 may respectively transfer a first driving voltage ELVDD and a second driving voltage ELVSS to the pixel PXij. In one or more embodiments, first and second initialization voltage lines VL3 and VL4 may respectively transfer a first initialization voltage VINT and a second initialization voltage VAINT to the pixel PXij.

The first transistor T1 may be connected between the first driving voltage line VL1 which may receive the first driving voltage ELVDD and the light-emitting element ED. The first transistor T1 may include a first electrode connected to the first driving voltage line VL1 via the fifth transistor T5, a second electrode connected to a pixel electrode (or, referred to as an anode) of the light-emitting element ED via the sixth transistor T6, and a third electrode (e.g., a gate electrode) connected to one end (e.g., a first node N1) of the capacitor Cst. The first transistor T1 may receive the data signal DT transferred by the j-th data line DLⱼ according to a switching operation of the second transistor T2 and supply driving current to the light-emitting element ED.

The second transistor T2 may be connected between the j-th data line DLⱼ and the first electrode of the first transistor T1. The second transistor T2 may include a first electrode connected to the j-th data line DLⱼ, a second electrode connected to the first electrode of the first transistor T1, and a third electrode (e.g., a gate electrode) connected to the i-th gate line GWLᵢ. The second transistor T2 may be turned on in response to a write scan signal GWᵢ transferred through the i-th gate line GWLᵢ and transfer the data signal DT transferred from the j-th data line DLⱼ to the first electrode of the first transistor T1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode (e.g., a gate electrode) connected to the i-th compensation scan line GCLᵢ. The third transistor T3 may be turned on in response to the i-th compensation scan signal GCᵢ transferred through the i-th compensation scan line GCLᵢ to connect the third electrode of the first transistor T1 and the second electrode of the first transistor T1 to each other, so that the first transistor T1 may be diode-connected.

The fourth transistor T4 may connected between the first initialization voltage line VL3 to which the first initialization voltage VINT is applied and the first node N1. The fourth transistor T4 may include a first electrode connected to the first initialization voltage line VL3 through which the first initialization voltage VINT may be transferred, a second electrode connected to the first node N1, and a third electrode (e.g., a gate electrode) connected to the i-th initialization scan line GILᵢ. The fourth transistor T4 may be turned on in response to the i-th initialization scan signal Glᵢ transferred through the i-th initialization scan line GILᵢ. The turned-on fourth transistor T4 may transfer the first initialization voltage VINT to the first node N1 and initialize a potential of the third electrode of the first transistor T1 (e.g., a potential of the first node N1).

The fifth transistor T5 may include a first electrode connected to the first driving voltage line VL1, a second electrode connected to the first electrode of the first transistor T1, and a third electrode (e.g., a gate electrode) connected to the i-th emission control line ECLᵢ. The sixth transistor T6 may include a first electrode connected to the second electrode of the first transistor T1, a second electrode connected to a pixel electrode (e.g., a second node N2) of the light-emitting element ED, and a third electrode (e.g., a gate electrode) connected to the i-th emission control line ECLᵢ.

The fifth and sixth transistors T5 and T6 may be concurrently (e.g., simultaneously) turned on in response to the i-th emission control signal EMᵢ transferred through the i-th emission control line ECLᵢ. The first driving voltage ELVDD may be applied through the turned-on fifth transistor T5 and may be compensated through the diode-connected first transistor T1, and then transferred to the light-emitting element ED through the sixth transistor T6.

The seventh transistor T7 may include a first electrode connected to the second initialization voltage line VL4 through which the second initialization voltage VAINT may be transferred, a second electrode connected to the second node N2, and a third electrode (e.g., a gate electrode) connected to the black scan line GBLᵢ. The second initialization voltage VAINT may have a voltage level lower than or equal to that of the first initialization voltage VINT.

The capacitor Cst may be connected (e.g., via one terminal) to the third electrode of the first transistor T1, and the capacitor Cst may be connected (e.g., via one terminal) to the first driving voltage line VL1. A cathode of the light-emitting element ED may be connected to the second driving voltage line VL2 which transfers the second driving voltage ELVSS. The second driving voltage ELVSS may have a relatively lower voltage level than the first driving voltage ELVDD.

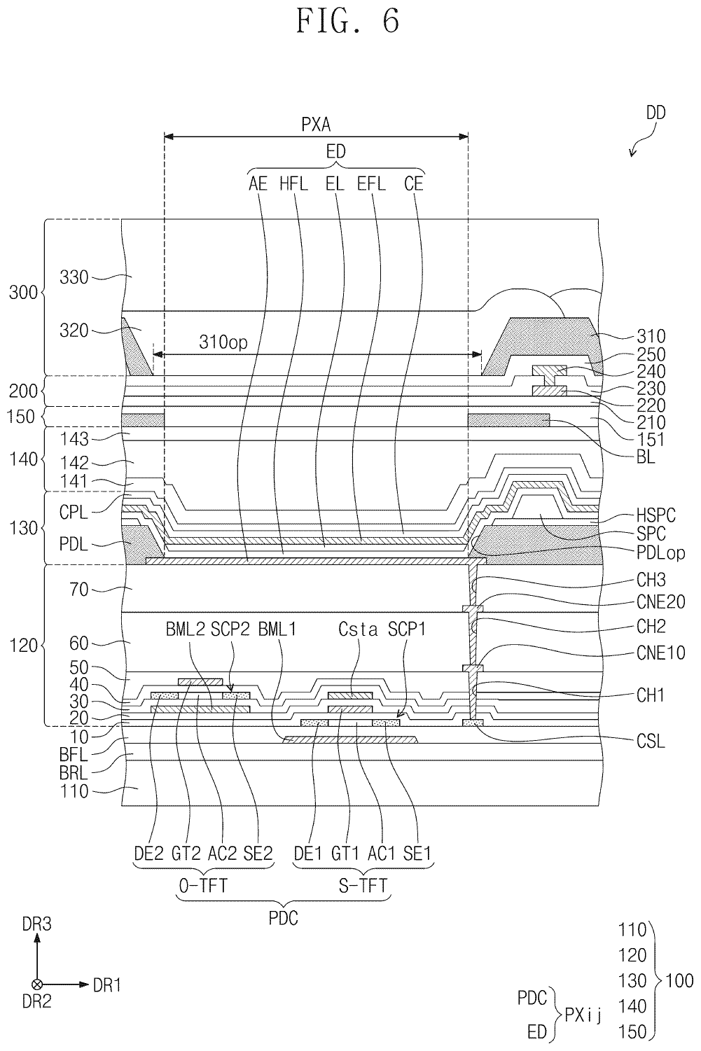

FIG. 6 depicts a cross-sectional view illustrating a portion of a display device DD according to one or more embodiments of the present disclosure.

Referring to FIG. 6, a display device DD may include a display panel 100, a light control layer 150, a sensor 200, and an anti-reflective layer 300. At least one of the sensor 200 and/or the anti-reflective layer 300 may not be provided according to an electronic apparatus to which the display device DD is utilized. In one or more embodiments, the display device DD may further include another component, e.g., a window, etc., in addition to components illustrated in the example of FIG. 6.

The display panel 100 may include a base layer 110, a barrier layer BRL, a buffer layer BFL, a circuit layer 120, an element layer 130, and an encapsulation layer 140.

The base layer 110 may be a glass substrate, a metal substrate, a polymer substrate, and/or the like. However, embodiments of the present disclosure are not limited thereto, and the base layer 110 may be an inorganic layer, an organic layer, and/or a composite material layer. In one or more embodiments of the present disclosure, the base layer 110 may include a plurality of sub-base layers. For example, one or more of the sub-base layers may each include at least one of a polyimide-based resin, an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and/or a perylene-based resin. As used herein, a “˜˜”-based resin may be considered as including a functional group of “˜˜”.

The barrier layer BRL may be arranged on the base layer 110 (as used herein, “arranged on” or “located on” may mean “above”). The buffer layer BFL may be arranged on the barrier layer BRL. The buffer layer BFL may prevent or reduce diffusion of metal atoms and/or impurities from the base layer 110 to a first semiconductor pattern SCP1. In one or more embodiments, the buffer layer BFL may adjust a rate of providing heat during a crystallization process for forming (or providing) the first semiconductor pattern SCP1, so that the first semiconductor pattern SCP1 may be uniformly formed (or provided).

The barrier layer BRL and/or the buffer layer BFL may each include a plurality of inorganic layers. The plurality of inorganic layers may each include at least one of silicon oxide, silicon nitride, silicon oxynitride, or amorphous silicon, but embodiments of the present disclosure are not particularly limited thereto.

A first bottom metal layer BML1 may be arranged between the barrier layer BRL and the buffer layer BFL. The first bottom metal layer BML1 may be referred to as a first lower layer, a first lower light-blocking layer, a first lower electrode layer, a first lower shielding layer, a first metal layer, a first electrode layer, a first shielding layer, or a first overlap layer. In one or more embodiments, the first bottom metal layer BML1 may be arranged between the one or more inorganic layers of the barrier layer BRL. In one or more embodiments of the present disclosure, the first bottom metal layer BML1 may be optimally provided.

One pixel PXij may include a light-emitting element ED and a pixel-driving circuit PDC. The circuit layer 120 may be arranged on the buffer layer BFL, and the element layer 130 may be arranged on the circuit layer 120. Referring to FIG. 6, the pixel-driving circuit PDC may be included in the circuit layer 120, and the light-emitting element ED may be included in the element layer 130.

FIG. 6 illustrates a silicon thin-film transistor S-TFT and an oxide thin-film transistor O-TFT of the pixel-driving circuit PDC. The silicon thin-film transistor S-TFT may be one of the first, second, fifth, sixth, and seventh transistors T1, T2, T5, T6, and T7 described with reference to FIG. 5, and the oxide thin-film transistor O-TFT may be one of the third and fourth transistors T3 and T4.

The first semiconductor pattern SCP1 may be arranged on the buffer layer BFL. The first semiconductor pattern SCP1 may include a silicon semiconductor. For example, the silicon semiconductor may include amorphous silicon, polycrystalline silicon, etc. For example, the first semiconductor pattern SCP1 may include relatively low temperature poly silicon.

FIG. 6 illustrates a portion of the first semiconductor pattern SCP1 that may be arranged on the buffer layer BFL, and the first semiconductor pattern SCP1 may be further arranged in another region. The first semiconductor pattern SCP1 may be arranged according to a rule across pixels. The first semiconductor pattern SCP1 may have a different electrical property according to if the first semiconductor pattern is doped or undoped (e.g., not doped). The first semiconductor pattern SCP1 may include a first region having relatively high conductivity and a second region having relatively low conductivity. The first region may be doped with an N-type dopant or a P-type dopant. A P-type transistor may include a doped region doped with a P-type dopant, and an N-type transistor may include a doped region doped with an N-type dopant. The second region may be an undoped region or a region doped with a relatively lower concentration compared to the first region.

The first region may have relatively higher conductivity than the second region and substantially serve as an electrode or a signal line. The second region may substantially correspond to an active region (or a channel) of a transistor. In one or more embodiments, a portion of the first semiconductor pattern SCP1 may be an active region of a transistor, another portion may be a source or drain of the transistor, and still another portion may be a connection electrode or a connection signal line.

A source region SE1, an active region AC1, and a drain region DE1 of the silicon thin-film transistor S-TFT may be formed (or provided) from the first semiconductor pattern SCP1. The source region SE1 and the drain region DE1 may extend in opposite directions from the active region AC1 in a cross-sectional view.

FIG. 6 illustrates a portion of a connection signal line CSL which may be formed (or provided) from the first semiconductor pattern SCP1. The connection signal line CSL may be electrically connected to the second electrode of the sixth transistor T6 (see FIG. 5) and the second electrode of the seventh transistor T7 (see FIG. 5).

The circuit layer 120 may include one or more inorganic layers and one or more organic layers. In one or more embodiments, the first to fifth insulating layers 10, 20, 30, 40, and 50 which may be sequentially stacked on the buffer layer BFL may be inorganic layers, and sixth and seventh insulating layers 60 and 70 may be organic layers. The first to fifth insulating layers 10, 20, 30, 40, and 50 may be referred to as inorganic insulating layers. In one or more embodiments, other insulating layers may be further added in addition to the insulating layers illustrated in FIG. 6, and at least a portion of the insulating layers illustrated in FIG. 6 may not be included.

The first insulating layer 10 may be arranged on the buffer layer BFL. The first insulating layer 10 may cover the first semiconductor pattern SCP1. The first insulating layer 10 may be an inorganic layer and/or an organic layer and have a single- or multi-layered structure. The first insulating layer 10 may include at least one of aluminum oxide, titanium oxide, silicon oxide, silicon nitride, silicon oxynitride, zirconium oxide, or hafnium oxide. In one or more embodiments, the first insulating layer 10 may be a single-layered silicon oxide layer. As well as the first insulating layer 10, an insulating layer of the circuit layer 120 to be described later may have a single- or multi-layered structure.

A gate electrode GT1 of the silicon thin-film transistor S-TFT may be arranged on the first insulating layer 10. The gate electrode GT1 may be a portion of a metal pattern. The gate electrode GT1 overlaps the active region AC1. In a process of doping the first semiconductor pattern SCP1, the gate electrode GT1 may function as a mask. The gate electrode GT1 may include titanium, silver, a silver-containing alloy, molybdenum, a molybdenum-containing alloy, aluminum, an aluminum-containing alloy, aluminum nitride, tungsten, tungsten nitride, copper, indium tin oxide, indium zinc oxide, and/or the like, but embodiments of the present disclosure are not limited thereto.

The second insulating layer 20 may be arranged on the first insulating layer 10 and cover the gate electrode GT1. The second insulating layer 20 may be an inorganic layer and have a single- or multi-layered structure. The second insulating layer 20 may include at least one of silicon oxide, silicon nitride, or silicon oxynitride. In one or more embodiments, the second insulating layer 20 may have a single-layered structure including a silicon nitride layer.

The third insulating layer 30 may be arranged on the second insulating layer 20. The third insulating layer 30 may be an inorganic layer and have a single- or multi-layered structure. For example, the third insulating layer 30 may have a multi-layered structure including a silicon oxide layer and a silicon nitride layer. One electrode Csta of the capacitor Cst (see FIG. 5) may be arranged between the second insulating layer 20 and the third insulating layer 30. In one or more embodiments, another one electrode of the capacitor Cst may be arranged between the first insulating layer 10 and the second insulating layer 20.

A second semiconductor pattern SCP2 may be arranged on the third insulating layer 30. The second semiconductor pattern SCP2 may include an oxide semiconductor. The oxide semiconductor may include one or more regions distinguished from each other according to if metal oxide is reduced or not. A region (hereinafter referred to as a “reduced region”) in which metal oxide may be reduced may have a relatively higher conductivity compared to a region (hereinafter referred to as a “non-reduced region”) in which metal oxide may not be reduced. The reduced region may substantially serve as a source/drain of a transistor or a signal line. The non-reduced region may substantially correspond to an active region (or a semiconductor region, channel) of the transistor. In one or more embodiments, a portion of the second semiconductor pattern SCP2 may be an active region of a transistor, another portion may be a source/drain region of the transistor, and still another portion may be a signal transfer region.

A source region SE2, an active region AC2, and a drain region DE2 of the oxide thin-film transistor O-TFT may be formed (or provided) from the second semiconductor pattern SCP2. The source region SE2 and the drain region DE2 may extend in opposite directions from the active region AC2 in a cross-sectional view.

The oxide thin-film transistor O-TFT may overlap a second bottom metal layer BML2. The second bottom metal layer BML2 may be referred to as a second lower layer, a second lower light-blocking layer, a second lower electrode layer, a second lower shielding layer, a second metal layer, a second electrode layer, a second shielding layer, or a second overlap layer.

Light incident from below the display panel 100 may be blocked (or reduced) by the second bottom metal layer BML2 and may not be provided to the active region AC2 of the oxide thin-film transistor O-TFT. The second bottom metal layer BML2 may be arranged between the second insulating layer 20 and the third insulating layer 30. The second bottom metal layer BML2 and the one electrode Csta of the capacitor Cst (see FIG. 5) may include the same material and may be formed (or provided) through the substantially similar (or same) process. In one or more embodiments of the present disclosure, the second bottom metal layer BML2 may not be provided.

The fourth insulating layer 40 may be arranged on the third insulating layer 30. The fourth insulating layer 40 may cover the second semiconductor pattern SCP2. The fourth insulating layer 40 may be an inorganic layer and have a single- or multi-layered structure. The fourth insulating layer 40 may include at least one of aluminum oxide, titanium oxide, silicon oxide, silicon nitride, silicon oxynitride, zirconium oxide, or hafnium oxide. In one or more embodiments, the fourth insulating layer 40 may have a single-layered structure including silicon oxide.

A gate electrode GT2 of the oxide thin-film transistor O-TFT may be on the fourth insulating layer 40. The gate electrode GT2 may be a portion of a metal pattern. The gate electrode GT2 may overlap the active region AC2. In a process of reducing the second semiconductor pattern SCP2, the gate electrode GT2 may function as a mask. In one or more embodiments of the present disclosure, the second bottom metal layer BML2 may function as a bottom gate electrode. For example, the second bottom metal layer BML2 and the gate electrode GT2 may be electrically connected to each other or receive the same signal. However, this configuration is an example, and embodiments of the present disclosure are not limited thereto.

The fifth insulating layer 50 may be disposed on the fourth insulating layer 40 and cover the gate electrode GT2. The fifth insulating layer 50 may be an inorganic layer and/or an organic layer and have a single- or multi-layered structure. For example, the fifth insulating layer 50 may have a multi-layered structure including a silicon oxide layer and a silicon nitride layer.

A first connection electrode CNE10 may be arranged on the fifth insulating layer 50. The first connection electrode CNE10 may be connected to the connection signal line CSL through a first contact hole CH1 passing through the first to fifth insulating layers 10, 20, 30, 40, and 50.

The sixth insulating layer 60 may be arranged on the fifth insulating layer 50. A second connection electrode CNE20 may be arranged on the sixth insulating layer 60. The second connection electrode CNE20 may be connected to the first connection electrode CNE10 through a second contact hole CH2 passing through the sixth insulating layer 60. The seventh insulating layer 70 may be arranged on the sixth insulating layer 60 and cover the second connection electrode CNE20.

The sixth insulating layer 60 and the seventh insulating layer 70 may each include an organic layer or an organic material. For example, the sixth insulating layer 60 and the seventh insulating layer 70 may each include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylate-based polymer, an imide-based polymer, an arylether-based polymer, an amide-based polymer, a fluorine-based polymer, a p-xylene-based polymer, a vinyl alcohol-based polymer, a blend thereof, and/or the like, but embodiments of the present disclosure are not limited to the example described above.

The element layer 130 including the light-emitting element ED may be arranged on the circuit layer 120. The light-emitting element ED may include a pixel electrode AE (or an anode), a first functional layer HFL, an emission layer EL, a second functional layer EFL, and a cathode CE (or a common electrode). The first functional layer HFL, the second functional layer EFL, and the cathode CE may be provided in common to the pixels.

The pixel electrode AE may be arranged on the seventh insulating layer 70. The pixel electrode AE may be connected to the second connection electrode CNE20 through a third contact hole CH3 passing through the seventh insulating layer 70. The pixel electrode AE may be a light-transmissive electrode, a semi-light-transmissive electrode, or a reflective electrode. In one or more embodiments, the pixel electrode AE may include a reflective layer which is formed (or provide) of silver, magnesium, aluminum, platinum, palladium, gold, nickel, neodymium, iridium, chromium, a compound thereof, and/or the like, and a transparent or translucent electrode layer which is formed (or provided) on the reflective layer. The transparent or translucent electrode layer may include at least one or more selected from the group consisting of indium tin oxide, indium zinc oxide, indium gallium zinc oxide, zinc oxide, or indium oxide, and/or aluminum-doped zinc oxide. For example, the pixel electrode AE may include a multi-layered structure in which indium tin oxide, silver, and indium tin oxide are sequentially stacked.

A pixel-defining film PDL may be arranged on the seventh insulating layer 70. A pixel-defining opening PDLop which exposes a portion of the pixel electrode AE may be defined in the pixel-defining film PDL. In one or more embodiments, the pixel-defining film PDL may cover an edge of the pixel electrode AE. Light-emitting regions PXA may be defined by pixel-defining openings PDLop which are defined in the pixel-defining film PDL. For example, one light-emitting region PXA may be defined in the light-emitting element ED.

The pixel-defining film PDL may have a light-absorbing property, and for example, the pixel-defining film PDL may have a black color. The pixel-defining film PDL may include a black coloring agent. The black coloring agent may include black dye or a black pigment. The black coloring agent may include carbon black, metal such as chromium, and/or an oxide thereof.

A first spacer HSPC may be arranged on the pixel-defining film PDL. A first protruding spacer SPC may be arranged on the first spacer HSPC. The first spacer HSPC and the first protruding spacer SPC may have an integrated shape and may be formed (or provided) of a substantially similar (or the same) material. For example, the first spacer HSPC and/or the first protruding spacer SPC may be formed (or provided) through a substantially similar (or the same) process with a half-tone mask. However, this is an example, and a embodiments of the present disclosure are not limited thereto. For example, the first spacer HSPC and the first protruding spacer SPC may include different materials and may be formed (or provide) through separate processes.

The first functional layer HFL may be arranged on the pixel electrode AE, the pixel-defining film PDL, the first spacer HSPC, and/or the first protruding spacer SPC. The first functional layer HFL may include a hole transport layer (HTL), include a hole injection layer (HIL), or include both a hole transport layer and a hole injection layer.

The emission layer EL may be arranged on the first functional layer HFL and arranged in a region that may correspond to the pixel-defining opening PDLop of the pixel-defining film PDL. The emission layer EL may include an organic material, an inorganic material, or an organic-inorganic material which emits light having a set (e.g., predetermined) color. The second functional layer EFL may be arranged on the first functional layer HFL and may cover the emission layer EL. The second functional layer EFL may include an electron transport layer (ETL), include an electron injection layer (EIL), or include both an electron transport layer and an electron injection layer. The cathode CE may be arranged on the second functional layer EFL.

The element layer 130 may further include a capping layer CPL arranged on the cathode CE. The capping layer CPL may serve to improve light emission efficiency according to aspects of constructive interference. The capping layer CPL may include, for example, a material having a refractive index of approximately 1.6 or more with respect to light having a wavelength of approximately 589 nm. The capping layer CPL may be an organic capping layer including an organic material, an inorganic capping layer including an inorganic material, or a composite capping layer including an organic material and an inorganic material. For example, the capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, and/or any combination thereof. The carbocyclic compound, the heterocyclic compound, and the amine group-containing compound may be optionally substituted with a substituent including O, N, S, Se, Si, F, Cl, Br, I, or any combination thereof.

The encapsulation layer 140 may be arranged on the element layer 130. The encapsulation layer 140 may include an inorganic layer 141, an organic layer 142, and an inorganic layer 143 which are sequentially stacked, but layers that may be included in the encapsulation layer 140 are not limited thereto.

The inorganic layers 141 and 143 may protect the element layer 130 from moisture and/or oxygen, and the organic layer 142 may protect the element layer 130 from foreign substances such as dust particles. The inorganic layers 141 and 143 may include a silicon nitride layer, a silicon oxynitride layer, a silicon oxide layer, a titanium oxide layer, an aluminum oxide layer, or the like. The organic layer 142 may include an acrylate-based organic layer, but an embodiment of the inventive concept is not particularly limited thereto.

The light control layer 150 may be arranged on the display panel 100. The light control layer 150 may include a light-blocking part BL and a cover layer 151.

The light-blocking part BL may be arranged to be separated (e.g., spaced apart) from the light-emitting region PXA. The light-blocking part BL may control (or select) a direction of light from the emission layer EL. The light-blocking part BL may include a first light-blocking part BLR (see FIG. 7), a second light-blocking part BLB (see FIG. 7), and a third light-blocking part BLG (see FIG. 7).

The light-blocking part BL may be a layer having a black color, and in one or more embodiments, the light-blocking part BL may include a black coloring agent. The black coloring agent may include black dye or a black pigment. The black coloring agent may include carbon black, metal such as chromium, or an oxide thereof.

The cover layer 151 may be arranged on the light-blocking part BL, and the cover layer 151 may cover the light-blocking part BL. The cover layer 151 may not be provided. In this case, a sensor base layer 210 to be described later may cover the light-blocking part BL.

The sensor 200 may be arranged on the light control layer 150. The sensor 200 may be referred to as a sensor, an input sensing layer, or an input sensing panel. The sensor 200 may include the sensor base layer 210, a first sensor conductive layer 220, a sensor insulating layer 230, a second sensor conductive layer 240, and a sensor cover layer 250.

The sensor base layer 210 may be arranged on the display panel 100. The sensor base layer 210 may be an inorganic layer including at least one of silicon nitride, silicon oxynitride, or silicon oxide. In one or more embodiments, the sensor base layer 210 may be an organic layer including an epoxy resin, an acryl resin, or an imide-based resin. The sensor base layer 210 may have a single-layered structure or a multi-layered structure in which layers are stacked along a third direction DR3.

The first sensor conductive layer 220 and the second sensor conductive layer 240 may each have a single-layered structure or a multi-layered structure in which layers are stacked along the third direction DR3.

The conductive layer having a single-layered structure may include a metal layer or a transparent conductive layer. The metal layer may include molybdenum (Mo), silver (Ag), titanium (Ti), copper (Cu), aluminum (Al), or an alloy thereof. The transparent conductive layer may include transparent conductive oxide such as indium tin oxide, indium zinc oxide, zinc oxide, or indium zinc tin oxide. In one or more embodiments, the transparent conductive layer may include a conductive polymer such as poly(3,4-ethylenedioxythiophene) (PEDOT), a metal nanowire, graphene, etc.

The conductive layer may have a multi-layered structure and may include metal layers. The metal layers may have, for example, a three-layered structure of titanium/aluminum/titanium. The conductive layer having a multi-layered structure may include at least one metal layer and at least one transparent conductive layer.

The sensor insulating layer 230 may be arranged between the first sensor conductive layer 220 and the second sensor conductive layer 240. The sensor insulating layer 230 may include an inorganic film. The inorganic film may include at least one of aluminum oxide, titanium oxide, silicon oxide, silicon nitride, silicon oxynitride, zirconium oxide, or hafnium oxide.

Alternatively, the sensor insulating layer 230 may include an organic film. The organic film may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

The sensor cover layer 250 may be arranged on the sensor insulating layer 230 and cover the second sensor conductive layer 240. The second sensor conductive layer 240 may include a conductive pattern. The sensor cover layer 250 may cover the conductive pattern and reduce or remove a probability that the conductive pattern will be damaged in a subsequent process. The sensor cover layer 250 may include an inorganic material. For example, the sensor cover layer 250 may include silicon nitride, but is not limited thereto. In one or more embodiments of the present disclosure, the sensor cover layer 250 may not be provided.

The anti-reflective layer 300 may be arranged on the sensor 200. The anti-reflective layer 300 may include a division layer 310, one or more of color filters 320, and a planarization layer 330.

The division layer 310 may be arranged to overlap the conductive pattern of the second sensor conductive layer 240. The sensor cover layer 250 may be arranged between the division layer 310 and the second sensor conductive layer 240. The division layer 310 may prevent (or reduce) external light reflection due to the second sensor conductive layer 240. A material included in the division layer 310 may not be limited thereto when the material absorbs light. The division layer 310 may be a layer having a black color, and in one or more embodiments, the division layer 310 may include a black coloring agent. The black coloring agent may include black dye or a black pigment. The black coloring agent may include carbon black, metal such as chromium, or an oxide thereof.

One or more division openings 310op may be defined in the division layer 310. The division openings 310op may respectively overlap one or more emission layers EL. The color filters 320 may be arranged to respectively correspond to the division openings 310op. The color filter 320 may transmit light provided from the emission layer EL overlapping the color filter 320.

The planarization layer 330 may cover the division layer 310 and the color filters 320. The planarization layer 330 may include an organic material and provide a flat surface to an upper surface of the planarization layer 330. In one or more embodiments, the planarization layer 330 may not be provided.

In one or more embodiments of the present disclosure, the anti-reflective layer 300 may include a reflection adjusting layer instead of the color filters 320. For example, in the illustration of FIG. 6, the color filters 320 may not be provided, and the reflection adjusting layer may be added in a place where the color filters 320 may not be provided. The reflection adjusting layer may selectively absorb light of a partial band among light reflected from inside a display panel and/or an electronic apparatus or light incident from outside a display panel and/or an electronic apparatus.

As an example, the reflection adjusting layer may absorb light in a first wavelength range of approximately 490 nm to approximately 505 nm and a second wavelength range of approximately 585 nm to approximately 600 nm, and a light transmittance in the first wavelength range and the second wavelength range may be approximately 40% or less. The reflection adjusting layer may absorb light of a wavelength out of wavelength ranges of red, green, and blue light which are emitted from the emission layer EL. As described above, the reflection adjusting layer may absorb light of a wavelength that does not belong to the wavelength range of red, green, or blue light which is emitted from the emission layer EL, and thus a decrease in luminance of a display panel and/or an electronic apparatus may be prevented, minimized, or reduced. In one or more embodiments, deterioration of light emission efficiency of the display panel and/or the electronic apparatus may be prevented, minimized, or reduced, and visibility may be improved.

The reflection adjusting layer may be provided as an organic material layer including dye, a pigment, or a combination thereof. The reflection adjusting layer may include a tetraazaporphyrin (TAP)-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, and a combination thereof.

In some embodiments, the reflection adjusting layer may have a transmittance in a range of approximately 64% to approximately 72%. The transmittance of the reflection adjusting layer may be adjusted according to a content of dye and/or a pigment included in the reflection adjusting layer.

In one or more embodiments of the present disclosure, the anti-reflective layer 300 may include a retarder and/or a polarizer. The anti-reflective layer 300 may include at least a polarizing film. In one or more embodiments, the anti-reflective layer 300 may be attached to the sensor 200 through an adhesive layer.

FIG. 7 depicts a plan view illustrating a portion of a display device DD according to one or more embodiments of the present disclosure.

Referring to FIGS. 4, 6, and 7, the display devices may include the display panel 100, the light control layer 150 arranged on the display panel 100, and a demultiplexer circuit DMC. The light control layer 150 may include a light-blocking part BL, and the light-blocking part BL may include a first light-blocking part BLR, a second light-blocking part BLB, and a third light-blocking part BLG. The first light-blocking part BLR, the second light-blocking part BLB, and the third light-blocking part BLG may each have a substantially round shape.

FIG. 7 illustrates a first to fourth gate lines GWL1, GWL2, GWL3, and GWL4, (1-1)-th to (4-2)-th data lines DL1-1, DL1-2, DL2-1, DL2-2, DL3-1, DL3-2, DL4-1, and DL4-2, a plurality of pixels PX11, PX12, PX13, PX14, PX21, PX22, PX23, PX24, PX31, PX32, PX33, PX34, PX41, PX42, PX43, and PX44, a demultiplexer circuit DMC, and first to fourth channel lines CL1, CL2, CL3, and CL4.

The one or more pixels PX11 to PX44 may each include a pixel-driving circuit PDC. The pixel-driving circuit PDC may be connected to corresponding one or more gate lines GWL1 to GWL4 and plurality of data lines DL1-1 to DL4-2. The pixel-driving circuit PDC may be electrically connected to the light-emitting element ED and control the light-emitting element ED.

The one or more pixels PX11 to PX44 may include one or more first pixels PX11, PX23, PX31, and PX43, one or more second pixels PX13, PX21, PX33, and PX41, and one or more third pixels PX12, PX14, PX22, PX24, PX32, PX34, PX42, and PX44 (e.g., a fourth pixel and fifth pixel in the claims).

A first light-emitting region in which light having a first color may be output and may be set (or defined) in each of the one or more first pixels PX11, PX23, PX31, and PX43.

A second light-emitting region in which light having a second color different from the first color may be output and may be set (or defined) in each of the one or more second pixels PX13, PX21, PX33, and PX41.

A third light-emitting region in which light having a third color different from the first color and the second color is out may be set (or defined) in each of the one or more third pixels PX12, PX14, PX22, PX24, PX32, PX34, PX42, and PX44. The first color may be red, the second color may be blue, and the third color may be green.

In one or more embodiments, the first to third light-emitting regions may each be provided in plurality and repeatedly having a set (or predetermined) arrangement in the active region 100A. For example, the first light-emitting region and the second light-emitting region may be alternately arranged along a first direction DR1 and be included in a ‘first group’. The third light-emitting region may be arranged along the first direction DR1 and may be included in a ‘second group’. The ‘first group’ and the ‘second group’ may each be provided in plurality, and the ‘first groups’ and the ‘second groups’ may be alternately arranged along a second direction DR2.

The one or more first pixels PX11, PX23, PX31, and PX43 may each include the pixel-driving circuit PDC and a first light-emitting element ED. The first light-emitting element ED may include a first anode AER and a first emission layer ELR. A first contact hole CNTR may be defined in the first anode AER. The first light-emitting element ED may be electrically connected to a corresponding pixel-driving circuit PDC through the first contact hole CNTR.

In the first pixel PX11, the pixel-driving circuit PDC may be electrically connected to the first gate line GWL1 and the (1-1)-th data line DL1-1.

The first light-blocking part BLR may be arranged on the first light-emitting element ED1 ED of the first pixel PX11. In a plan view, the first light-blocking part BLR may be arranged to surround an edge of the first emission layer ELR of the first pixel PX11. In one or more embodiments, an opening OPR of the first light-blocking part BLR may overlap the first emission layer ELR of the first pixel PX11.

According to the present disclosure, the first light-blocking part BLR may overlap a portion of the first emission layer ELR of the first pixel PX11, and the opening of the first light-blocking part BLR may overlap the rest of the first emission layer ELR of the first pixel PX11. The portion of the first emission layer ELR may be a portion adjacent to the edge of the first emission layer ELR. Here, the first light-blocking part BLR may control a viewing angle of light which is emitted from the first pixel PX11. The display device may narrow a viewing angle using the light control layer 150, thereby limiting users who may view a screen. Thus, the display device having improved display quality may be provided.

In the first pixel PX23, the pixel-driving circuit PDC may be electrically connected to the second gate line GWL2 and the (3-2)-th data line DL3-2.

In a plan view, the light-blocking part BL may not overlap the first light-emitting element ED1 of the first pixel PX23. That is, the light-blocking part BL may not be arranged on the first light-emitting element ED of the first pixel PX23.

In the first pixel PX31, the pixel-driving circuit PDC may be electrically connected to the third gate line GWL3 and the (1-1)-th data line DL1-1. The first light-blocking part BLR may be arranged on the first light-emitting element ED of the first pixel PX31. For example, the first light-blocking part BLR may be arranged on the first pixels PX11 and PX31 arranged in odd rows.

In the first pixel PX43, the pixel-driving circuit PDC may be electrically connected to the fourth gate line GWL4 and the (3-2)-th data line DL3-2. The light-blocking part BL may not be arranged on the first light-emitting element ED1 of the first pixel PX43. For example, the light-blocking part BL may not be arranged on the first pixels PX23 and PX43 arranged in even rows.

The one or more second pixels PX13, PX21, PX33, and PX41 may each include the pixel-driving circuit PDC and a second light-emitting element ED2. The second light-emitting element ED2 may include a second anode AEB and a second emission layer ELB. A second contact hole CNTB may be provided in the second anode AEB. The second light-emitting element ED2 may be electrically connected to a corresponding pixel-driving circuit PDC through the second contact hole CNTB.

In the second pixel PX13, the pixel-driving circuit PDC may be electrically connected to the first gate line GWL1 and the (3-1)-th data line DL3-1.

In a plan view, the light-blocking part BL may not overlap the second light-emitting element ED2 of the second pixel PX13. In one or more embodiments, the light-blocking part BL may not be arranged on the second light-emitting element ED2 of the second pixel PX13.

In the second pixel PX21, the pixel-driving circuit PDC may be electrically connected to the second gate line GWL2 and the (1-2)-th data line DL1-2.

The second light-blocking part BLB may be arranged on the second light-emitting element ED2 of the second pixel PX21. In a plan view, the second light-blocking part BLB may be arranged to be around (e.g., surround) an edge of the second emission layer ELB of the second pixel PX21. In one or more embodiments, an opening OPB of the second light-blocking part BLB may overlap the second emission layer ELB of the second pixel PX21.

In the second pixel PX33, the pixel-driving circuit PDC may be electrically connected to the third gate line GWL3 and the (3-1)-th data line DL3-1. The light-blocking part BL may not be arranged on the second light-emitting element ED2 of the second pixel PX33. For example, the light-blocking part BL may not be arranged on the second pixels PX13 and PX33 arranged in odd rows.

In the second pixel PX41, the pixel-driving circuit PDC may be electrically connected to the fourth gate line GWL4 and the (1-2)-th data line DL1-2. The second light-blocking part BLB may be arranged on the second light-emitting element ED2 of the second pixel PX41. For example, the second light-blocking part BLB may be arranged on the second pixels PX21 and PX41 arranged in even rows.

The one or more third pixels PX12, PX14, PX22, PX24, PX32, PX34, PX42, and PX44 may each include the pixel-driving circuit PDC and a third light-emitting element ED3. The third light-emitting element ED3 may include a third anode AEG and a third emission layer ELG. A third contact hole CNTG may be defined in the third anode AEG. The third light-emitting element ED3 may be electrically connected to a corresponding pixel-driving circuit PDC through the third contact hole CNTG.

In the third pixel PX12, the pixel-driving circuit PDC may be electrically connected to the first gate line GWL1 and a (2-1)-th data line DL2-1 (e.g., a third data line in the claims).

In a plan view, the light-blocking part BL may not overlap the third light-emitting element ED3 of the third pixel PX12. That is, the light-blocking part BL may not be arranged on the third light-emitting element ED3 of the third pixel PX12.

In the third pixel PX14, the pixel-driving circuit PDC may be electrically connected to the first gate line GWL1 and the (4-1)-th data line DL4-1.

In the third pixel PX32, the pixel-driving circuit PDC may be electrically connected to the third gate line GWL3 and the (2-1)-th data line DL2-1.

In the third pixel PX34, the pixel-driving circuit PDC may be electrically connected to the third gate line GWL3 and the (4-1)-th data line DL4-1.

The light-blocking part BL may not be arranged on the third light-emitting element ED3 of each of the third pixels PX12, PX14, PX32, and PX34. For example, the light-blocking part BL may not be arranged on the third pixels PX12, PX14, PX32, and PX34 arranged in odd rows.

The third pixels PX12, PX14, PX32, and PX34 of which the light-blocking part BL may not be arranged on each third light-emitting element ED3 may be referred to as a (3-1)-th pixel (e.g., a fourth pixel in the claims).

In the third pixel PX22, the pixel-driving circuit PDC may be electrically connected to the second gate line GWL2 and a (2-2)-th data line DL2-2 (e.g., a fourth data line in the claims).

The third light-blocking part BLG may be arranged on the third light-emitting element ED3 of the third pixel PX22. In a plan view, the third light-blocking part BLG may be arranged to be around (e.g., surround) an edge of the third emission layer ELG of the third pixel PX22. In one or more embodiments, an opening OPG of the third light-blocking part BLG may overlap the third emission layer ELG of the third pixel PX22.

In the third pixel PX24, the pixel-driving circuit PDC may be electrically connected to the second gate line GWL2 and the (4-2)-th data line DL4-2.

In the third pixel PX42, the pixel-driving circuit PDC may be electrically connected to the fourth gate line GWL4 and the (2-2)-th data line DL2-2.

In the third pixel PX44, the pixel-driving circuit PDC may be electrically connected to the fourth gate line GWL4 and the (4-2)-th data line DL4-2.

The third light-blocking part BLG may be arranged on the third light-emitting element ED3 of each of the third pixels PX22, PX24, PX42, and PX44. For example, the third light-blocking part BLG may be disposed on the third pixels PX22, PX24, PX42, and PX44 arranged in even rows.

The third pixels PX22, PX24, PX42, and PX44 of which the third light-blocking part BLG is arranged on each third light-emitting element ED3 may be referred to as a (3-2)-th pixel (e.g., a fifth pixel in the claims).

The demultiplexer circuit DMC may be arranged to be separated (e.g., spaced apart) from the one or more pixels PX11 to PX44 in the second direction DR2.

The demultiplexer circuit DMC may include first and second line control lines CTL1 and CTL2 and first to eighth switches SW1, SW2, SW3, SW4, SW5, SW6, SW7, and SW8.

The demultiplexer circuit DMC may receive a first line control signal CTO or a second line control signal CTE via the first and second line control lines CTL1 and CTL2. The demultiplexer circuit DMC may receive a data signal from the data-driving circuit DDC via the plurality of channel lines CL1 to CL4.

The first to eighth switches SW1 to SW8 may be respectively electrically connected to the (1-1)-th to (4-2)-th data lines DL1-1 to DL4-2.

The first switch SW1 may be connected between the (1-1)-th data line DL1-1 (e.g., a first data line in the claims) and the data-driving circuit DDC. The second switch SW2 may be connected between the (1-2)-th data line DL1-2 (e.g., a second data line in the claims) and the data-driving circuit DDC. The third switch SW3 may be connected between the (2-1)-th data line DL2-1 and the data-driving circuit DDC. The fourth switch SW4 may be connected between the (2-2)-th data line DL2-2 and the data-driving circuit DDC. The fifth switch SW5 may be connected between the (3-1)-th data line DL3-1 and the data-driving circuit DDC. The sixth switch SW6 may be connected between the (3-2)-th data line DL3-2 and the data-driving circuit DDC. The seventh switch SW7 may be connected between the (4-1)-th data line DL4-1 and the data-driving circuit DDC. The eighth switch SW8 may be connected between the (4-2)-th data line DL4-2 and the data-driving circuit DDC.

If the demultiplexer circuit DMC receives an activated first line control signal CTO, the first, third, fifth, and seventh switches SW1, SW3, SW5, and SW7 may be activated, and the data signal may be transferred to the pixels PX11 to PX14 and PX31 to PX34 arranged in odd rows.

If the demultiplexer circuit DMC receives an activated second line control signal CTE, the second, fourth, sixth, and eighth switches SW2, SW4, SW6, and SW8 may be activated, and the data signal may be transferred to the pixels PX21 to PX24 and PX41 to PX44 arranged in even rows.

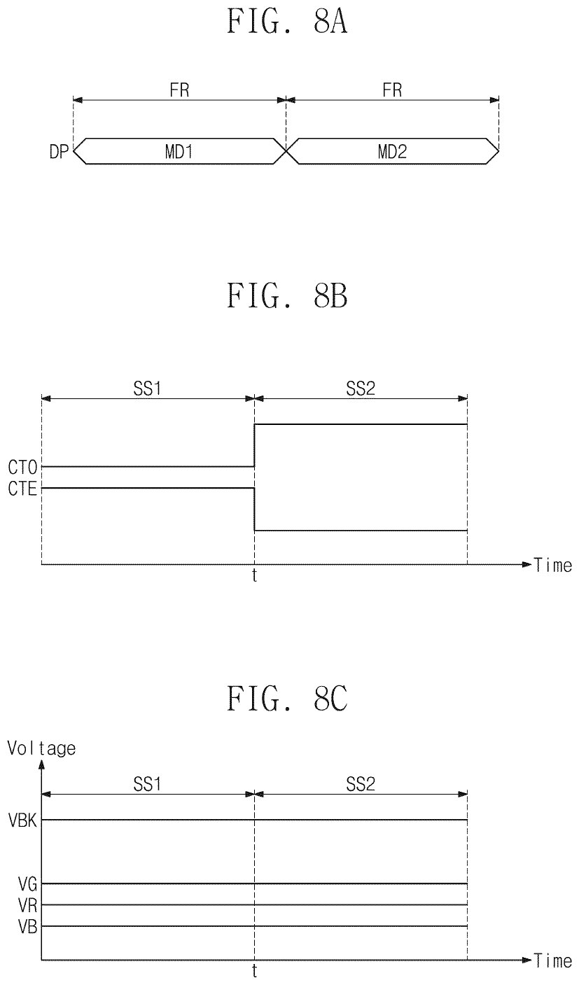

FIG. 7 depicts a plan view illustrating a portion of a display device according to one or more embodiments of the present disclosure. FIG. 8A depicts a diagram illustrating a first mode and a second mode according to one or more embodiments of the present disclosure. FIG. 8B depicts a graph of first and second line control signals according to one or more embodiments of the present disclosure. FIG. 8C depicts a graph of a voltage level of a data signal according to one or more embodiments of the present disclosure. For example, in FIG. 8C, a vertical axis may represent a voltage, and a horizontal axis may represent time.

Referring to FIGS. 7, 8A, 8B, and 8C, a display panel DP may operate in a first mode MD1 or in a second mode MD2. The first mode MD1 and/or the second mode MD2 may be operated in units of frame FR. One frame FR may include a first period SS1 and a second period SS2. FIG. 8A illustrates the display panel DP that may operate in the first mode MD1 in a first frame FR and may operate in the second mode MD2 in a second frame FR.

The first mode MD1 may be a viewing angle control mode in which a screen is displayed at a narrow viewing angle. A viewing angle may be narrowed in the first mode MD1, thereby limiting users who view the screen. For example, in the first mode MD1, the pixels PX11, PX21, PX22, PX24, PX31, PX41, PX42, and PX44 arranged under the light-blocking part BL may emit corresponding red, green, and blue light, and remaining pixels PX12, PX13, PX14, PX23, PX32, PX33, PX34, and PX43 not overlapping the light-blocking part BL may display black.

The second mode MD2 may be a normal mode in which a viewing angle is not controlled. For example, in the second mode MD2, the one or more pixels PX11 to PX44 may emit corresponding red, green, and blue light.

In the first mode MD1, the display panel DP may operate in the first period SS1 and the second period SS2 consecutive to the first period SS1. Hereinafter, an operation of each of the first period SS1 and the second period SS2 in the first mode MD1 will be described. FIG. 8C and following description illustrates signals that may be output when a white image is displayed in the active region 100A (see FIG. 4). In one or more embodiments, red, green, and blue light may be emitted during one frame FR so as to display the white image.

A first line control signal CTO may be activated in the first period SS1. For example, an activation level of the first line control signal CTO may be a substantially low level. In one or more embodiments, the first, third, fifth, and seventh switches SW1, SW3, SW5, and SW7 may be activated.

A second line control signal CTE may be deactivated in the first period SS1. For example, a deactivation level of the second line control signal CTE may be a substantially high level. In one or more embodiments, the second, fourth, sixth, and eighth switches SW2, SW4, SW6, and SW8 may be deactivated.

If the first switch SW1 is activated, a data signal having a first voltage level VR may be transferred to the (1-1)-th data line DL1-1. In one or more embodiments, during the first period SS1, the first switch SW1 may be activated, and the data-driving circuit DDC (see FIG. 4) may transfer the data signal having the first voltage level VR to the (1-1)-th data line DL1-1. The data signal having the first voltage level VR may be referred to as a first data signal.

The first pixels PX11 and PX31 electrically connected to the (1-1)-th data line DL1-1 may emit red light during the first period SS1.

If the third switch SW3 is activated, a data signal having a black voltage level VBK may be transferred to the (2-1)-th data line DL2-1.

If the fifth switch SW5 is activated, a data signal having the black voltage level VBK may be transferred to the (3-1)-th data line DL3-1.

If the seventh switch SW7 is activated, a data signal having the black voltage level VBK may be transferred to the (4-1)-th data line DL4-1.

During the first period SS1, the third, fifth, and seventh switches SW3, SW5, and SW7 may be activated, and the data-driving circuit DDC (see FIG. 4) may transfer data signals having the black voltage level VBK to the (2-1)-th, (3-1)-th, and (4-1)-th data lines DL2-1, DL3-1, and DL4-1. The data signal having the black voltage level VBK may be referred to as a (2-1)-th data signal (e.g., a third data signal in the claims).

The (3-1)-th pixels PX12 and PX32 electrically connected to the (2-1)-th data line DL2-1 may display black during the first period SS1. The second pixels PX13 and PX33 electrically connected to the (3-1)-th data line DL3-1 may display black. The (3-1)-th pixels PX14 and PX34 electrically connected to the (4-1)-th data line DL4-1 may display black.

At a set (e.g., predetermined) time point t, the first line control signal CTO may be deactivated, and the second period SS2 may start. The second line control signal CTE may be activated in the second period SS2. For example, an activation level of the second line control signal CTE may be a substantially low level. In one or more embodiments, the second, fourth, sixth, and eighth switches SW2, SW4, SW6, and SW8 may be activated.

The first line control signal CTO may be deactivated in the second period SS2. For example, a deactivation level of the first line control signal CTO may be high level. In one or more embodiments, the first, third, fifth, and seventh switches SW1, SW3, SW5, and SW7 may be deactivated.

If the second switch SW2 is activated, a data signal having a second voltage level VB may be transferred to the (1-2)-th data line DL1-2. During the second period SS2, the second switch SW2 may be activated, and the data-driving circuit DDC (see FIG. 4) may transfer the data signal having the second voltage level VB to the (1-2)-th data line DL1-2. The data signal having the second voltage level VB may be referred to as a second data signal.

The second pixels PX21 and PX41 electrically connected to the (1-2)-th data line DL1-2 may emit blue light during the second period SS2.

If the fourth switch SW4 is activated, a data signal having a third voltage level VG may be transferred to the (2-2)-th data line DL2-2. During the second period SS2, the fourth switch SW4 may be activated, and the data-driving circuit DDC (see FIG. 4) may transfer the data signal having the third voltage level VG to the (2-2)-th data line DL2-2. The data signal having the third voltage level VG may be referred to as a (2-2)-th data signal (e.g., a fourth data signal).

The (3-2)-th pixels PX22 and PX42 electrically connected to the (2-2)-th data line DL2-2 may emit green light during the second period SS2.

If the sixth switch SW6 is activated, a data signal having the black voltage level VBK may be transferred to the (3-2)-th data line DL3-2. During the second period SS2, the sixth switch SW6 may be activated, and the data-driving circuit DDC (see FIG. 4) may transfer the data signal having the black voltage level VBK to the (3-2)-th data line DL3-2.

The first pixels PX23 and PX43 electrically connected to the (3-2)-th data line DL3-2 may display black during the second period SS2.

If the eighth switch SW8 is activated, a data signal having the third voltage level VG may be transferred to the (4-2)-th data line DL4-2. During the second period SS2, the eighth switch SW8 may be activated, and the data-driving circuit DDC (see FIG. 4) may transfer the data signal having the third voltage level VG to the (4-2)-th data line DL4-2.

The (3-2)-th pixels PX24 and PX44 electrically connected to the (4-2)-th data line DL4-2 may emit green light during the second period SS2.

The black voltage level VBK may have higher voltage level than the first to third voltage levels VR, VB, and VG. The black voltage level VBK may have a voltage level of a data signal based on which black is displayed.

The second voltage level VB may have lower voltage level than the first voltage level VR, and the third voltage level VG may have higher voltage level than the first voltage level VR. The first voltage level VR may have a voltage level of a data signal based on which red is displayed. The second voltage level VB may have a voltage level of a data signal based on which blue is displayed. The third voltage level VG may have a voltage level of a data signal based on which green is displayed.

In one or more embodiments of the present disclosure, operation may be performed by dividing one frame FR into a first period SS1 and a second period SS2 using the demultiplexer circuit DMC. In one or more embodiments, the data lines DL1-1 to DL4-2 may be separately operated in the first period SS1 and the second period SS2. Each of the data lines DL1-1 to DL4-2 may be provided with a data signal having a constant voltage level. Thus, if a single color image is output, voltage swing in which a voltage level provided to each of the data lines DL1-1 to DL4-2 changes may be prevented, removed, or reduced. Noise may be prevented (or reduced) from being transferred to the cathode CE (see FIG. 6) of the display panel 100 (see FIG. 6) and the sensor 200 (see FIG. 6) due to the voltage swing. Thus, the display device DD (see FIG. 6) having improved display quality and sensing reliability may be provided.

In one or more embodiments, according to the present disclosure, in the display device DD (see FIG. 6) that operates in the first mode MD1, the pixels PX11, PX21, PX22, PX24, PX31, PX41, PX42, and PX44 disposed under the light-blocking part BL may emit corresponding red, green, and blue light, and the remaining pixels PX12, PX13, PX14, PX23, PX32, PX33, PX34, and PX43 not overlapping the light-blocking part BL may display black through the first period SS1 and the second period SS2. Thus, a white image having controlled viewing angle may be displayed in the active region 100A (see FIG. 4) of the display device DD (see FIG. 4). That is, the display device DD (see FIG. 6) may narrow a viewing angle using the light control layer 150 (see FIG. 6), thereby limiting users who view a screen. Thus, the display device DD (see FIG. 6) having improved display quality may be provided.

In the second mode MD2, the display device DD may operate in the first period SS1 and the second period SS2. Hereinafter, an operation of each of the first period SS1 and the second period SS2 in the second mode MD2 will be described.

A first line control signal CTO may be activated in the first period SS1, and the first, third, fifth, and seventh switches SW1, SW3, SW5, and SW7 may be activated. A second line control signal CTE may be deactivated in the first period SS1.

If the first switch SW1 is activated, a data signal having the first voltage level VR may be transferred to the (1-1)-th data line DL1-1. During the first period SS1, the first switch SW1 may be activated, and the data-driving circuit DDC (see FIG. 4) may transfer the data signal having the first voltage level VR to the (1-1)-th data line DL1-1.

The first pixels PX11 and PX31 electrically connected to the (1-1)-th data line DL1-1 may emit red light during the first period SS1.

If the third switch SW3 is activated, a data signal having the third voltage level VG may be transferred to the (2-1)-th data line DL2-1. During the first period SS1, the third switch SW3 may be activated, and the data-driving circuit DDC (see FIG. 4) may transfer the data signal having the third voltage level VG to the (2-1)-th data line DL2-1.

The (3-1)-th pixels PX12 and PX32 electrically connected to the (2-1)-th data line DL2-1 may emit green light during the first period SS1.

If the fifth switch SW5 is activated, a data signal having the second voltage level VB may be transferred to the (3-1)-th data line DL3-1. During the first period SS1, the fifth switch SW5 may be activated, and the data-driving circuit DDC (see FIG. 4) may transfer the data signal having the second voltage level VB to the (3-1)-th data line DL3-1.

The second pixels PX13 and PX33 electrically connected to the (3-1)-th data line DL3-1 may emit blue light during the first period SS1.

If the seventh switch SW7 is activated, a data signal having the third voltage level VG may be transferred to the (4-1)-th data line DL4-1. During the first period SS1, the seventh switch SW7 may be activated, and the data-driving circuit DDC (see FIG. 4) may transfer the data signal having the third voltage level VG to the (4-1)-th data line DL4-1.

The (3-1)-th pixels PX14 and PX34 electrically connected to the (4-1)-th data line DL4-1 may emit green light during the first period SS1.

At a set (e.g., predetermined) time point t, the first line control signal CTO may be deactivated, and the second line control signal CTE may be activated in the second period SS2. In one or more embodiments, the second, fourth, sixth, and eighth switches SW2, SW4, SW6, and SW8 may be activated. The first line control signal CTO may be deactivated in the second period SS2.

If the second switch SW2 is activated, a data signal having the second voltage level VB may be transferred to the (1-2)-th data line DL1-2. During the second period SS2, the second switch SW2 may be activated, and the data-driving circuit DDC (see FIG. 4) may transfer the data signal having the second voltage level VB to the (1-2)-th data line DL1-2.

The second pixels PX21 and PX41 electrically connected to the (1-2)-th data line DL1-2 may emit blue light during the second period SS2.

If the fourth switch SW4 is activated, a data signal having the third voltage level VG may be transferred to the (2-2)-th data line DL2-2. During the second period SS2, the fourth switch SW4 may be activated, and the data-driving circuit DDC (see FIG. 4) may transfer the data signal having the third voltage level VG to the (2-2)-th data line DL2-2.

The (3-2)-th pixels PX22 and PX42 electrically connected to the (2-2)-th data line DL2-2 may emit green light during the second period SS2.

If the sixth switch SW6 is activated, a data signal having the first voltage level VR may be transferred to the (3-2)-th data line DL3-2. During the second period SS2, the sixth switch SW6 may be activated, and the data-driving circuit DDC (see FIG. 4) may transfer the data signal having the first voltage level VR to the (3-2)-th data line DL3-2.

The first pixels PX23 and PX43 electrically connected to the (3-2)-th data line DL3-2 may emit red light during the second period SS2.

If the eighth switch SW8 is activated, a data signal having the third voltage level VG may be transferred to the (4-2)-th data line DL4-2. During the second period SS2, the eighth switch SW8 may be activated, and the data-driving circuit DDC (see FIG. 4) may transfer the data signal having the third voltage level VG to the (4-2)-th data line DL4-2.

The (3-2)-th pixels PX24 and PX44 electrically connected to the (4-2)-th data line DL4-2 may emit green light during the second period SS2.

In one or more embodiments of the present disclosure, in the display device DD (see FIG. 6) that operates in the second mode MD2, the one or more pixels PX11 to PX44 may emit corresponding red, green, and blue light through the first period SS1 and the second period SS2. Thus, a white image having a wider viewing angle than that in the first mode MD1 may be displayed in the active region 100A (see FIG. 4) of the display device DD (see FIG. 4). In one or more embodiments, the display device DD (see FIG. 6) may control a viewing angle of an image according to a mode. Thus, the display device DD (see FIG. 6) having improved display quality may be provided.

TABLE 1

| Displayed image | Comparative Example | Example |
|---|---|---|
| White | 71 mW (milliwatt) | 0 mW |
| Red | 50 mW | 0 mW |
| Green | 71 mW | 0 mW |
| Blue | 57 mW | 0 mW |

Table 1 may show power consumption at a data line of each of Comparative Example and Example according to types (kinds) of an image which is displayed in the active region 100A (see FIG. 4) of the display device DD (see FIG. 4). In one or more embodiments, a scan rate of the display device DD (see FIG. 4) may be approximately 120 hertz (Hz), and resolution of the display device DD (see FIG. 4) may be, for example, 3840×BML10. However, embodiments of the present disclosure are not limited thereto and may be provided in one or more suitable implementations. For example, resolution of the display device DD (see FIG. 4) may be 3088×1440. The 3840×BML10 resolution may be referred to as wide quad high definition plus (WQHD+). The Comparative Example may include a display device without the demultiplexer circuit DMC. A data signal may be transferred to a plurality of pixels through one data line. A data signal having different voltage levels in the first period SS1 and the second period SS2 may be transferred to a data line. For example, a data signal of which the first voltage level VR and the second voltage level VB swing according to time may be provided to a data line connected to a first pixel row in which the first pixels PX11 and PX31 and the second pixels PX21 and PX41 are arranged.

If a data signal having different voltage level enters the same data line, voltage swing may occur, and power may be consumed. For example, when an image which is displayed in the active region 100A (see FIG. 4) is a white image, power consumption of approximately 71 mW may occur due to the voltage swing, if the image is a red image, power consumption of approximately 50 mW may occur due to the voltage swing, if the image is a green image, power consumption of approximately 71 mW may occur due to the voltage swing, and if the image is a blue image, power consumption of about 57 mW may occur due to the voltage swing.

The display device DD (see FIG. 4), in one or more embodiments of the present disclosure, may correspond to Example. The display device DD (see FIG. 4) may include the demultiplexer circuit DMC.

The demultiplexer circuit DMC may receive the first and/or second line control signal CTO or CTE and activate the first, third, fifth, and seventh switches SW1, SW3, SW5, and SW7 or the second, fourth, sixth, and eighth switches SW2, SW4, SW6, and SW8. Accordingly, a data signal having one voltage level may be transferred to one data line. That is, the voltage swing may not occur in the Example. For example, if an image which is displayed in the active region 100A (see FIG. 4) is a white image, a red image, a green image, or a blue image, power consumption of about 0 mW may occur.

In one or more embodiments of the present disclosure, operation may be performed by dividing one frame FR into the first period SS1 and the second period SS2 using the demultiplexer circuit DMC. Here, the data lines DL1-1 to DL4-2 may be separately operated in the first period SS1 and the second period SS2. The data lines DL1-1- to DL4-2 may be provided with a data signal having a constant voltage level. Thus, if a single color image is output, voltage swing in which a voltage level provided to the data lines DL1-1 to DL4-2 changes may be prevented, removed, or reduced. Thus, the display device DD (see FIG. 4) having reduced power consumption may be provided.

TABLE 2

| Displayed image | Comparative Example | Example |
|---|---|---|
| White | −24 dbV (decibel volt) | −96 dbV |
| Red | −28 dbV | −96 dbV |
| Green | −24 dbV | −96 dbV |
| Blue | −28 dbV | −96 dbV |

Table 2 may show a potential change of the cathode CE (see FIG. 6) due to noise of each of Comparative Example and Example according to types (kinds) of images that are displayed in the active region 100A (see FIG. 4) of the display device DD (see FIG. 4). In one or more embodiments, a scan rate of the display device DD (see FIG. 4) may be approximately 120 hertz (Hz), and resolution of the display device DD (see FIG. 4) may be 3840×BML10. However, embodiments of the present disclosure are not limited thereto and may be provided in one or more suitable implementations. For example, resolution of the display device DD (see FIG. 4) may be 3088×1440. In the Comparative Example, the voltage swing may distort a voltage of the cathode CE (see FIG. 6) of the display panel 100 (see FIG. 6), thereby deteriorating (or decreasing)_display quality. For example, if an image which is displayed in the active region 100A (see FIG. 4) is a white image, a potential change of the cathode CE (see FIG. 6) may be approximately −24 dbV, if the image is a red image, a potential change of the cathode CE (see FIG. 6) may be approximately −28 dbV, if the image is a green image, a potential change of the cathode CE (see FIG. 6) may be approximately −24 dbV, and if the image is a blue image, a potential change of the cathode CE (see FIG. 6) may be approximately −28 dbV. In the Comparative Example, in a display device, a potential change of the cathode CE (see FIG. 6) may be different according to which image is displayed. Thus, noise may occur, and display quality may be deteriorated (or reduced).

In one or more embodiments, the noise may be transferred by a parasitic capacitor which is formed (or provided) between the cathode CE (see FIG. 6) and the sensor 200 (see FIG. 6), thereby deteriorating (or reducing) a signal-to-noise ratio (SNR) of the sensor 200 (see FIG. 6).

In the Example, the voltage swing may not occur due to a driving method described with reference to FIGS. 8A to 8C. For example, if an image which is displayed in the active region 100A (see FIG. 4) is a white image, a red image, a green image, or a blue image, a potential change of the cathode CE (see FIG. 6) may be substantially constant at approximately −96 dbV.

In one or more embodiments of the present disclosure, in the display device DD (see FIG. 6), a potential change of the cathode CE (see FIG. 6) may be substantially constant regardless of which image is displayed. Accordingly, noise may be reduced or removed. Thus, the display device DD (see FIG. 6) having improved (or increased) display quality and sensing reliability may be provided.

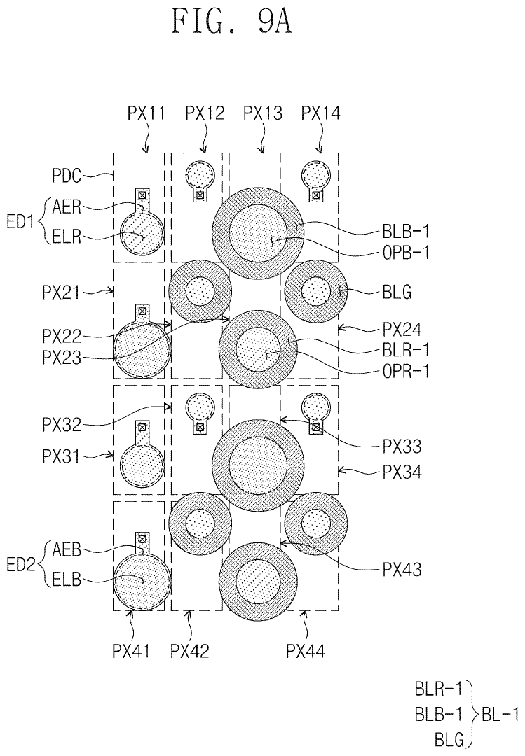

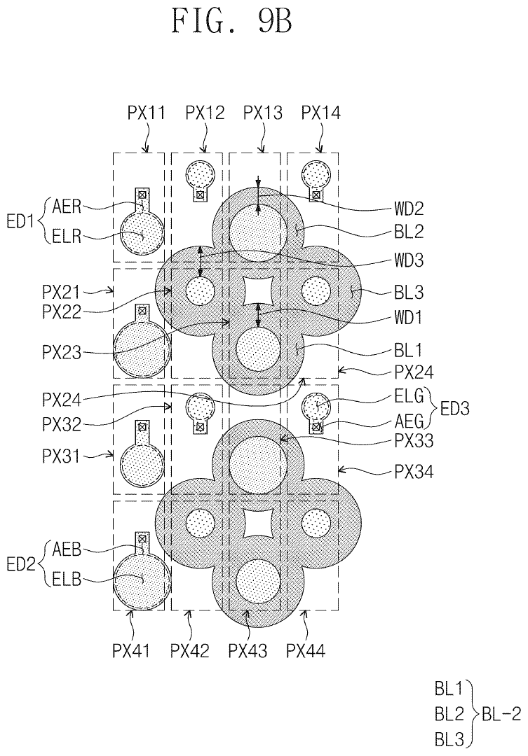

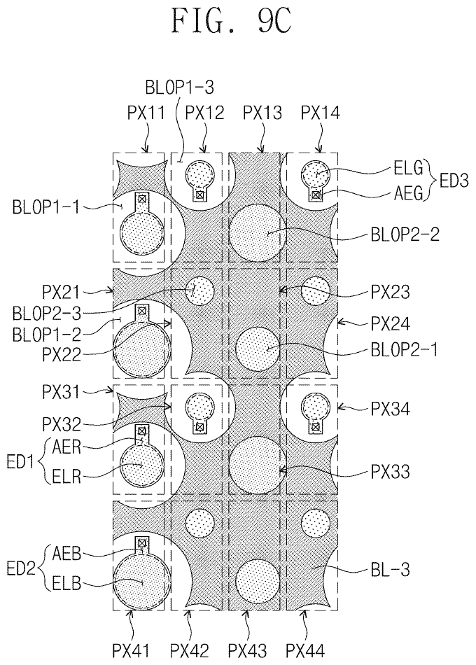

FIG. 9A depicts a plan view showing arrangement of a light-blocking part according to one or more embodiments of the present disclosure. In reference to FIG. 9A, a component that was described with reference to FIG. 7 may be referred to utilizing the same reference numerals or symbols, and description thereof may not be provided in detail.

Referring to FIG. 9A, a light-blocking part BL-1 may include a first light-blocking part BLR-1, a second light-blocking part BLB-1, and the third light-blocking part BLG.

The first light-blocking part BLR-1 may be arranged on the first light-emitting element ED1 of the first pixel PX23. In a plan view, the first light-blocking part BLR-1 may be arranged to be around (e.g., surround) an edge of the first emission layer ELR of the first pixel PX23. In one or more embodiments, an opening OPR-1 of the first light-blocking part BLR-1 may overlap the first emission layer ELR of the first pixel PX23.

The first light-blocking part BLR-1 may be arranged on the first light-emitting element ED1 of the first pixel PX43. In a plan view, the first light-blocking part BLR-1 may be arranged to be around (e.g., surround) an edge of the first emission layer ELR of the first pixel PX43.

The second light-blocking part BLB-1 may be arranged on the second light-emitting element ED2 of the second pixel PX13. In a plan view, the second light-blocking part BLB-1 may be arranged to be around (e.g., surround) an edge of the second emission layer ELB of the second pixel PX13. In one or more embodiments, an opening OPB-1 of the second light-blocking part BLB-1 may overlap the second emission layer ELB of the second pixel PX13.

The second light-blocking part BLB-1 may be arranged on the second light-emitting element ED2 of the second pixel PX33. In a plan view, the second light-blocking part BLB-1 may be arranged to surround an edge of the second emission layer ELB of the second pixel PX33.

The first light-blocking part BLR-1 may not be arranged on the first light-emitting element ED1 of each of the first pixels PX11 and PX31. In a plan view, the first light-blocking part BLR-1 may not overlap the first light-emitting element ED1 of each of the first pixels PX11 and PX31.

The second light-blocking part BLB-2 may not be arranged on the second light-emitting element ED2 of each of the second pixels PX21 and PX41. In a plan view, the second light-blocking part BLB-1 may not overlap the second light-emitting element ED2 of each of the second pixels PX21 and PX41.

FIG. 9B is a plan view showing arrangement of a light-blocking part according to one or more embodiments of the present disclosure. In reference to FIG. 9B, components described in reference to FIGS. 7 and 9A may be referred to using the same reference numerals or symbols, and description thereof may not be provided.

Referring to FIG. 9B, a light-blocking part BL-2 may further include a first light-blocking portion BL1, a second light-blocking portion BL2, and a third light-blocking portion BL3.

The first light-blocking portion BL1 may be arranged on the first light-emitting element ED1 of each of the first pixels PX23 and PX43. The first light-blocking portion BL1 may be arranged to be around (e.g., surround) an edge of the first emission layer ELR of each of the first pixels PX23 and PX43 by a first width WD1.

The second light-blocking portion BL2 may be arranged on the second light-emitting element ED2 of each of the second pixels PX13 and PX33. The second light-blocking portion BL2 may be arranged to be around (e.g., surround) an edge of the second emission layer ELB of each of the second pixels PX13 and PX33 by a second width WD2. In one or more embodiments, the second width WD2 may be relatively narrower than the first width WD1.

The third light-blocking portion BL3 may be arranged on the third light-emitting element ED3 of each of the third pixels PX22, PX24, PX42, and PX44. The third light-blocking portion BL3 may be arranged to be around (e.g., surround) an edge of the third emission layer ELG of each of the third pixels PX22, PX24, PX42, and PX44 by a third width WD3. In one or more embodiments, the third width WD3 may be relatively wider than the first width WD1.

Outer diameters of the first light-blocking portion BL1, the second light-blocking portion BL2, and the third light-blocking portion BL3 may be the substantially similar (or the same).

An inner diameter of each of the first light-blocking portion BL1, the second light-blocking portion BL2, and the third light-blocking portion BL3 may be set (defined) to correspond to the pixel-defining opening PDLop (see FIG. 6) of the element layer 130 (see FIG. 6).

The first light-blocking portion BL1, the second light-blocking portion BL2, and the third light-blocking portion BL3 may have an integrated shape.

FIG. 9C depicts a plan view showing arrangement of a light-blocking part according to one or more embodiments of the present disclosure. In reference to FIG. 9C, components described in reference to FIG. 7 may be referred to using the same reference numerals or symbols, and description thereof may not be provided.

Referring to FIGS. 6 and 9C, a light-blocking part BL-3 may be arranged on a display panel DP. The light-blocking part BL-3 may cover an upper surface of the display panel DP.

One or more openings may be set (or defined) in the light-blocking part BL-3. The one or more openings may include one or more first openings BLOP1-1, BLOP1-2, and BLOP1-3 (e.g., first openings in the claims) and one or more second openings BLOP2-1, BLOP2-2, and BLOP2-3 (e.g., second openings in the claims).

The one or more first openings BLOP1-1 may be respectively defined on the first pixels PX11 and PX31. In a plan view, the first opening BLOP1-1 may overlap the first light-emitting element ED1. For example, the first opening BLOP1-1 may cover the first light-emitting element ED1. The one or more first openings BLOP1-1 may overlap respective first emission layers ELR of the first pixels PX11 and PX31.

The one or more first openings BLOP1-2 may be respectively set (or defined) on the second pixels PX21 and PX41. In a plan view, the first opening BLOP1-2 may overlap the second light-emitting element ED2. For example, the first opening BLOP1-2 may cover the second light-emitting element ED2. The plurality of first openings BLOP1-2 may overlap respective second emission layers ELB of the second pixels PX21 and PX41.

The one or more first openings BLOP1-3 may be respectively defined on the third pixels PX12, PX14, PX32, and PX34. In a plan view, the first opening BLOP1-3 may overlap the third light-emitting element ED3. For example, the first opening BLOP1-3 may cover the third light-emitting element ED3. The plurality of first openings BLOP1-3 may overlap respective third emission layers ELG of the third pixels PX12, PX14, PX32, and PX34.

The one or more second openings BLOP2-1 to BLOP2-3 may be set (or defined) in the light-blocking part BL-3 as having a relatively smaller size than the one or more first openings BLOP1-1 to BLOP1-3.

The one or more second openings BLOP2-1 may be respectively set (or defined) on the first pixels PX23 and PX43. In a plan view, the second opening BLOP2-1 may overlap the first emission layer ELR. The one or more second openings BLOP2-1 may overlap respective first emission layers ELR of the first pixels PX23 and PX43. The one or more second openings BLOP2-1 may have a relatively smaller size than the one or more first openings BLOP1-1 and may be set (or defined) in the light-blocking part BL-3.

The one or more second openings BLOP2-2 may be respectively defined on the second pixels PX13 and PX33. In a plan view, the second opening BLOP2-2 may overlap the second emission layer ELB. The one or more second openings BLOP2-2 may overlap respective second emission layers ELB of the second pixels PX13 and PX33. The one or more second openings BLOP2-2 may have a relatively smaller size than the plurality of first openings BLOP1-2 and may be set (or defined) in the light-blocking part BL-3.

The one or more second openings BLOP2-3 may be respectively set (or defined) on the third pixels PX22, PX24, PX42, and PX44. In a plan view, the second opening BLOP2-3 may overlap the third emission layer ELG. The one or more second openings BLOP2-3 may overlap respective third emission layers ELG of the third pixels PX22, PX24, PX42, and PX44. The one or more second openings BLOP2-3 may have a relatively smaller size than the one or more first openings BLOP1-3 and may be set (or defined) in the light-blocking part BL-3.

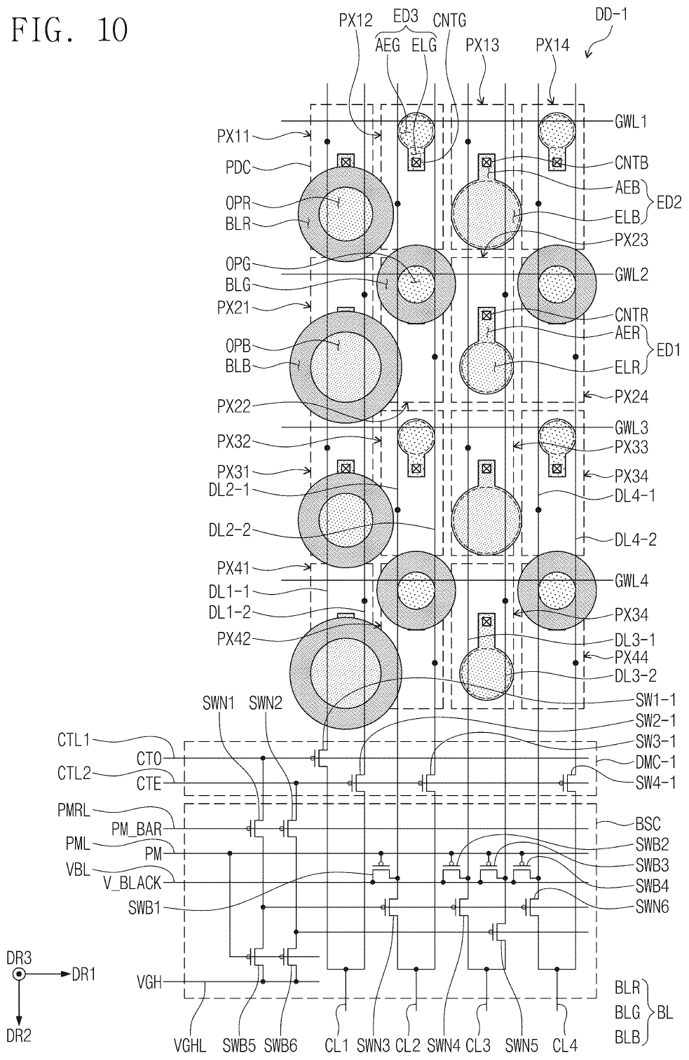

FIG. 10 depicts a plan view illustrating a portion of a display device according to one or more embodiments of the present disclosure. In reference to FIG. 10, components described in reference to FIG. 7 may be referred to using the same reference numerals or symbols, and description thereof may not be provided.

Referring to FIGS. 6 and 10, a display device DD-1 may include the display panel 100, the light control layer 150 disposed on the display panel 100, a demultiplexer circuit DMC-1, and a black signal provider circuit BSC. The light control layer 150 may include the light-blocking part BL, and the light-blocking part BL may include the first light-blocking part BLR, the second light-blocking part BLB, and the third light-blocking part BLG.

The demultiplexer circuit DMC-1 and the black signal provider circuit BSC may receive a data signal from the data-driving circuit DDC (see FIG. 4) via the plurality of channel lines CL1 to CL4.

The demultiplexer circuit DMC-1 may include first and second line control lines CTL1 and CTL2 and (1-1)-th to (4-1)-th switches SW1-1, SW2-1, SW3-1, and SW4-1.

If the demultiplexer circuit DMC-1 receives an activated first line control signal CTO, the (1-1)-th switch SW1-1 may be activated, and the data signal may be transferred to the first pixels PX11 and PX31.

If the demultiplexer circuit DMC-1 receives an activated second line control signal CTE, the (2-1)-th, (3-1)-th, and (4-1)-th switches SW2-1, SW3-1, and SW4-1 may be activated, and the data signal may be transferred to the second and third pixels PX21, PX22, PX24, PX41, PX42, and PX44.

The black signal provider circuit BSC may include first to third black control lines PML, PMRL, and VGHL, a black signal line VBL, first to sixth normal switches SWN1, SWN2, SWN3, SWN4, SWN5, and SWN6, and first to sixth black switches SWB1, SWB2, SWB3, SWB4, SWB5, and SWB6.

The first black control line PML may receive a first black control signal PM from the driving controller TC (see FIG. 4). If the black signal provider circuit BSC receives an activated first black control signal PM, the first to sixth black switches SWB1 to SWB6 may be activated.

The second black control line PMRL may receive a second black control signal PM_BAR from the driving controller TC (see FIG. 4). If the black signal provider circuit BSC receives an activated second black control signal PM_BAR, the first to second normal switches SWN1 and SWN2 may be activated.

The third black control line VGHL may receive a third black control signal VGH from the driving controller TC (see FIG. 4). If the fifth to sixth black switches SWB5 and SWB6 are activated, the third black control signal VGH may deactivate the third to sixth normal switches SWN3 to SWN6.

The black signal line VBL may receive a black signal V_BLACK from the driving controller TC (see FIG. 4). The black signal V_BLACK may be a signal based on which black is displayed in the light-emitting element ED (see FIG. 6).

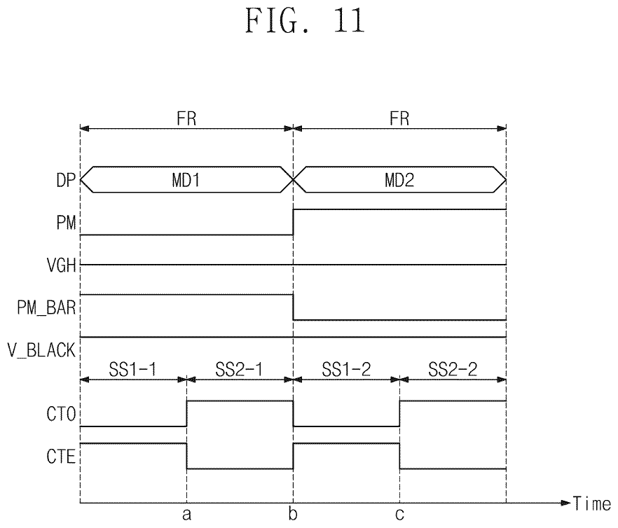

FIG. 11 depicts a diagram illustrating a first mode and a second mode according to one or more embodiments of the present disclosure. In reference to FIG. 11, components described in reference to FIGS. 8A to 8C may be referred to using the same reference numerals or symbols, and description thereof may not be provided.

Referring to FIGS. 10 and 11, a display panel DP may operate in a first mode MD1 or a second mode MD2.

A first black control signal PM may be a signal that is switched according to a mode. The first black control signal PM may be activated in the first mode MD1 and deactivated in the second mode MD2. For example, the first black control signal PM may have substantially low level in the first mode MD1 and may have a substantially high level in the second mode MD2.

A second black control signal PM_BAR may have a reverse phase of the first black control signal PM. The second black control signal PM_BAR may be deactivated in the first mode MD1 and activated in the second mode MD2. For example, the second black control signal PM_BAR may have a relatively high level in the first mode MD1 and may have a relatively low level in the second mode MD2.

A black signal V_BLACK may have substantially the same voltage level as the black voltage level VBK (see FIG. 8C). The black signal V_BLACK may have a voltage level of a data signal based on which black is displayed.

A third black control signal VGH may have a substantially high level. The third black control signal VGH may have a voltage level suitable for deactivating the third to sixth normal switches SWN3 to SWN6. For example, the third black control signal VGH may be referred to as a gate high signal.

The first black control signal PM may be activated during the first mode MD1. Thus, the first to sixth black switches SWB1 to SWB6 may be activated. The first and/or second normal switches SWN1 and SWN2 may be deactivated.

If the first black switch SWB1 is activated, the black signal V_BLACK may be transferred to the (2-1)-th data line DL2-1. If the second black switch SWB2 is activated, the black signal V_BLACK may be transferred to the (3-1)-th data line DL3-1. If the third black switch SWB3 is activated, the black signal V_BLACK may be transferred to the (3-2)-th data line DL3-2. If the fourth black switch SWB4 is activated, the black signal V_BLACK may be transferred to the (4-1)-th data line DL4-1.

If the fifth to sixth black switches SWB5 and SWB6 are activated, the third black control signal VGH may deactivate the third to sixth normal switches SWN3 to SWN6. The pixels PX12, PX13, PX14, PX23, PX32, PX33, PX34, and PX43 which display black may be disconnected from the data-driving circuit DDC (see FIG. 4) during the first mode MD1 due to the deactivated third to sixth normal switches SWN3 to SWN6. Thus, the black signal V_BLACK may be provided to the pixels PX12, PX13, PX14, PX23, PX32, PX33, PX34, and PX43 which display black during the first mode MD1.

The first mode MD1 may be operated in a (1-1)-th period SS1-1 and a (2-1)-th period SS2-1.

A first line control signal CTO may be activated in the (1-1)-th period SS1-1. In one or more embodiments, the (1-1)-th switch SW1-1 may be activated, and a data signal may be transferred to the (1-1)-th data line DL1-1. The first pixels PX11 and PX31 electrically connected to the (1-1)-th data line DL1-1 may emit red light during the (1-1)-th period SS1-1.

At a first time point a, the first line control signal CTO may be deactivated, and the (2-1)-th period SS2-1 may start. A second line control signal CTE may be activated in the (2-1)-th period SS2-1. In one or more embodiments, the (2-1)-th, (3-1)-th, and (4-1)-th switches SW2-1, SW3-1, and SW4-1 may be activated, and a data signal may be transferred to each of the (1-2)-th data line DL1-2, the (2-2)-th data line DL2-2, and the (4-2)-th data line DL4-2.

The second pixels PX21 and PX41 electrically connected to the (1-2)-th data line DL1-2 may emit blue light during the (2-1)-th period SS2-1.

The (3-2)-th pixels PX22, PX24, PX42, and PX44 electrically connected to the (2-2)-th data line DL2-2 and the (4-2)-th data line DL4-2 may emit green light during the (2-1)-th period SS2-1.

In one or more embodiments, operation may be performed by dividing one frame FR into the (1-1)-th period SS1-1 and the (2-1)-th period SS2-1 using the demultiplexer circuit DMC-1. In one or more embodiments, the data lines DL1-1 to DL4-2 may be separately operated in the (1-1)-th period SS1-1 and the (2-1)-th period SS2-1. Each of the data lines DL1-1 to DL4-2 may be provided with a data signal having a substantially constant voltage level. Thus, if a single-color image is output, voltage swing in which voltage level provided to each of the data lines DL1-1 to DL4-2 changes may be prevented, removed, or reduced. Noise may be prevented (or reduced) from being transferred to the cathode CE (see FIG. 6) of the display panel 100 (see FIG. 6) and the sensor 200 (see FIG. 6) due to the voltage swing. Thus, the display device DD-1 having improved (or increased) display quality and sensing reliability may be provided.

In one or more embodiments, according to the present disclosure, in the display device DD-1 that operates in the first mode MD1, the pixels PX11, PX21, PX22, PX24, PX31, PX41, PX42, and PX44 arranged under the light-blocking part BL may be to emit corresponding red, green, and blue light, and the remaining pixels PX12, PX13, PX14, PX23, PX32, PX33, PX34, and PX43 not overlapping the light-blocking part BL may display black based on the black signal V_BLACK through the (1-1)-th period SS1-1 and the (2-1)-th period SS2-1. Thus, a white image having a controlled viewing angle may be displayed in the active region 100A (see FIG. 4) of the display device DD-1. In one or more embodiments, the display device DD-1 may have a narrow viewing angle using the light control layer 150 (see FIG. 6), thereby limiting users who may view a screen. Thus, the display device DD-1 having improved (or increased) display quality may be provided.

At a second time point b, the display panel DP may operate in the second mode MD2. The first black control signal PM may be deactivated during the second mode MD2. Thus, the first to sixth black switches SWB1 to SWB6 may be deactivated. The first to second normal switches SWN1 and SWN2 may be activated.

The second mode MD2 may be operated in a (1-2)-th period SS1-2 and a (2-2)-th period SS2-2.

In the (1-2)-th period SS1-2, the first line control signal CTO may be activated, and the first to second normal switches SWN1 and SWN2 may be activated. If the first to second normal switches SWN1 and SWN2 are activated, the first line control signal CTO may activate the third, fourth, and sixth normal switches SWN3, SWN4, and SWN6.

If the third normal switch SWN3 is activated, a data signal may be transferred to the (2-1)-th data line DL2-1. The (3-1)-th pixels PX12 and PX32 electrically connected to the (2-1)-th data line DL2-1 may emit green light during the (1-2)-th period SS1-2.

If the fourth normal switch SWN4 is activated, a data signal may be transferred to the (3-1)-th data line DL3-1. The second pixels PX13 and PX33 electrically connected to the (3-1)-th data line DL3-1 may emit blue light during the (1-2)-th period SS1-2.

If the sixth normal switch SWN6 is activated, a data signal may be transferred to the (4-1)-th data line DL4-1. The (3-1)-th pixels PX14 and PX34 electrically connected to the (4-1)-th data line DL4-1 may emit green light during the (1-2)-th period SS1-2.

In the (1-2)-th period SS1-2, the (1-1)-th switch SW1-1 may be activated, and a data signal may be transferred to the (1-1)-th data line DL1-1. The first pixels PX11 and PX31 electrically connected to the (1-1)-th data line DL1-1 may emit red light during the first period SS1.

At a third time point c, the first line control signal CTO may be deactivated, and the (2-2)-th period SS2-2 may start.

In the (2-2)-th period SS2-2, the second black control signal PM_BAR and the second line control signal CTE may be activated, and the first and/or second normal switches SWN1 and SWN2 may be activated. If the first and/or second normal switches SWN1 and SWN2 are activated, the second line control signal CTE may activate the fifth normal switch SWN5.

If the fifth normal switch SWN5 is activated, a data signal may be transferred to the (3-2)-th data line DL3-2. The first pixels PX23 and PX43 electrically connected to the (3-2)-th data line DL3-2 may emit red light during the (2-2)-th period SS2-2.

In the (2-2)-th period SS2-2, the (2-1)-th, (3-1)-th, and (4-1)-th switches SW2-1, SW3-1, and SW4-1 may be activated, and a data signal may be transferred to each of the (1-2)-th data line DL1-2, the (2-2)-th data line DL2-2, and the (4-2)-th data line DL4-2.

The second pixels PX21 and PX41 electrically connected to the (1-2)-th data line DL1-2 may emit blue light during the (2-2)-th period SS2-2.

The (3-2)-th pixels PX22, PX24, PX42, and PX44 electrically connected to the (2-2)-th data line DL2-2 and the (4-2)-th data line DL4-2 may emit green light during the (2-2)-th period SS2-2.

In one or more embodiments, in the display device DD-1 that operates in the second mode MD2, the one or more pixels PX11 to PX44 may emit corresponding red, green, and blue light through the (1-2)-th period SS1-2 and the (2-2)-th period SS2-2. Thus, a white image having wider viewing angle than that in the first mode MD1 may be displayed in the active region 100A (see FIG. 4) of the display device DD-1. In one or more embodiments, the display device DD-1 may control a viewing angle of an image according to a mode. Thus, the display device DD-1 having improved (or increased) display quality may be provided.

In one or more embodiments, the black signal provider circuit BSC may transfer the black signal V_BLACK received from the driving controller TC (see FIG. 4) to the data lines DL2-1, DL3-1, DL3-2, and DL4-1 in the first mode MD1. The data-driving circuit DDC (see FIG. 4) may exclude a data signal having the black voltage level VBK (see FIG. 8C) and transfer only a data signal having the first to third voltage level VR, VB, and VG (see FIG. 8C). Thus, the display device DD-1 having reduced power consumption may be provided.

According to the description above, in a display device that operates in a first mode and a second mode, pixels arranged under a light-blocking part may be to emit corresponding red, green, and blue light, and remaining pixels not overlapping the light-blocking part may display black through a first period and a second period. Thus, a white image having a controlled viewing angle may be displayed in an active region of the display device. In one or more embodiments, the display device may have a relatively narrow viewing angle utilizing the light-blocking part, thereby limiting users who may view a screen. Thus, the display device having improved (or increased) display quality may be provided.

In one or more embodiments, operation may be performed by dividing one frame into a first period and a second period using a demultiplexer circuit. In one or more embodiments, a data line may be separately operated in the first period and the second period. Each data line may be provided with a data signal having a substantially constant voltage level. Thus, if a single color image is output, a voltage swing in which a voltage level provided to each data line may change may be prevented, removed, or reduced. Noise may be prevented (or reduced) from being transferred to a cathode of a display panel and a sensor due to the voltage swing. Thus, a display device having an improved (on increased) display quality and sensing reliability may be provided.

In one or more embodiments, a black signal provider circuit may transfer a black signal received from a driving controller to data lines in a first mode. A data-driving circuit may exclude (or reduced) a data signal having a black voltage level and transfer only a data signal having first to third voltage level. Thus, a display device having reduced power consumption may be provided.

Although one or more embodiments of the present disclosure have been described, it may be understood that the present disclosure should not be limited to these embodiments, but changes and modifications may be made by one of ordinary skilled in the art within the scope of the present disclosure as hereinafter described. Therefore, the technical scope of the present disclosure is not limited to the embodiments described in the detailed description of the specification, but should be determined by the claims.

What is claimed is:

1. A display device comprising:
a display panel configured to operate in one or more frames, and comprising a first data line, a second data line, and one or more pixels comprising:
a first pixel comprising a first light-emitting element and a first pixel circuit connected to the first data line; and
a second pixel comprising a second light-emitting element and a second pixel circuit connected to the second data line;
a light control layer above the display panel, comprising a light-blocking part, and configured to control light emitted from the one or more pixels;
a demultiplexer circuit electrically connected to the display panel, and comprising a first switch connected to the first data line, and a second switch connected to the second data line; and
a data-driving circuit connected to the demultiplexer circuit, and configured to provide a data signal comprising:
a first data signal comprising a first voltage level to the first data line based on activation of the first switch; and
a second data signal comprising a second voltage level that is different from the first voltage level to the second data line based on activation of the second switch.

2. The display device of claim 1, wherein the first light-emitting element comprises a first emission layer, and the second light-emitting element comprises a second emission layer, and
wherein the light-blocking part surrounds the first emission layer and the second emission layer in plan view, and defines a first opening overlapping the first emission layer and a second opening overlapping the second emission layer.

3. The display device of claim 2, wherein the display panel further comprises a third data line and a fourth data line,
wherein the one or more pixels comprise one or more third pixels comprising a third pixel circuit and a third light-emitting element, and
wherein the one or more third pixels comprises:
a fourth pixel electrically connected to the third data line, and
a fifth pixel electrically connected to the fourth data line.

4. The display device of claim 3, wherein the third light-emitting element comprises a third emission layer,
wherein the light-blocking part surrounds the third emission layer of the fourth pixel, and does not overlap the third emission layer of the fifth pixel, in plan view,
wherein the light-blocking part defines a third opening overlaps the third emission layer of the fourth pixel.

5. The display device of claim 4, wherein the data signal further comprises a third data signal and a fourth data signal, and
wherein the demultiplexer circuit further comprises a third switch connected to the third data line and the data-driving circuit and a fourth switch connected to the fourth data line and the data-driving circuit.

6. The display device of claim 5, wherein the data-driving circuit is configured to provide the third data signal to the third data line based on activation of the third switch.

7. The display device of claim 6, wherein the third data signal corresponds to black being displayed in the third light-emitting element.

8. The display device of claim 6, wherein the data-driving circuit is configured to provide the fourth data signal to the fourth data line based on activation of the fourth switch.

9. The display device of claim 8, wherein the fourth data signal comprises a third voltage level that is different from the first voltage level and the second voltage level.

10. The display device of claim 5, further comprising a black signal provider circuit configured to provide a black signal to the one or more third pixels, and comprising a black switch configured to control the black signal, and
wherein the display panel is configured to operate in a first mode or in a second mode different from the first mode.

11. The display device of claim 10, wherein the black signal provider circuit is configured to provide the black signal to the third data line based on activation of the black switch in the first mode.

12. The display device of claim 11, wherein the data-driving circuit is configured to provide the fourth data signal to the third data line based on activation of a normal switch in the second mode.

13. The display device of claim 1, wherein the first light-emitting element comprises a first emission layer,
wherein the second light-emitting element comprises a second emission layer,
wherein the light-blocking part comprises:
a first light-blocking portion surrounding the first emission layer, and spaced from an edge of the first emission layer by a first width, in plan view; and
a second light-blocking portion surrounding the second emission layer, and spaced from an edge of the second emission layer by a second width, in plan view, the second width being less than the first width.

14. The display device of claim 13, wherein the first light-blocking portion and the second light-blocking portion are integral.

15. The display device of claim 1, wherein the light-blocking part cover a surface of the display panel, and defines first openings overlapping the first light-emitting element and the second light-emitting element in a plan view, and second openings that are smaller than the first openings.

16. An electronic apparatus comprising:
a display panel configured to operate in one or more frames and comprising a first pixel and a second pixel;
a light control layer arranged on the display panel and comprising a light-blocking part;
a data-driving circuit configured to provide a data signal to the display panel; and
a demultiplexer circuit electrically connected to the data-driving circuit and the display panel,
wherein the light-blocking part is configured to control light emitted from the first pixel and the second pixel,
wherein the data signal comprising a first data signal comprising a first voltage level and a second data signal comprising a second voltage level different from the first voltage level, and
wherein the demultiplexer circuit configured to transfer the first data signal to the first pixel, and transfer the second data signal to the second pixel.

17. The electronic apparatus of claim 16, wherein the first pixel is configured to receive the data signal based on the one or more frames, and
wherein the second pixel is configured to receive the data signal based on the one or more frames.

18. The electronic apparatus of claim 16, wherein the first pixel comprises a first emission layer, and the second pixel comprises a second emission layer, and
the light blocking part surrounds each of the first emission layer and the second emission layer in a plan view, and the light blocking part defines an opening overlapping each of the first emission layer and the second emission layer.

19. The electronic apparatus of claim 18, wherein the display panel further comprises one or more third pixels, and
wherein the one or more third pixels a comprise a fourth pixel and a fifth pixel.

20. The electronic apparatus of claim 19, wherein the one or more third pixels comprise a third emission layer, and
wherein the light-blocking part further surrounds the third emission layer of the fourth pixel, and does not overlap the third emission layer of the fourth pixel, in a plan view,
wherein the opening further overlaps the third emission layer of the fourth pixel.

21. The electronic apparatus of claim 20, wherein the data signal further comprises a third data signal and a fourth data signal, and
wherein the fourth data signal is based on black displayed in the third emission layer.

22. The electronic apparatus of claim 21, wherein the fourth data signal comprises a third voltage level different from the first voltage level and the second voltage level.

23. The electronic apparatus of claim 16, wherein the first pixel comprises a first emission layer, and the second pixel comprises a second emission layer,
wherein the light-blocking part comprises a first light-blocking portion and a second light-blocking portion,
wherein the first light-blocking portion surrounds the first emission layer, and
wherein the second light-blocking portion surrounds the second emission layer.

24. The electronic apparatus of claim 23, wherein the first light-blocking portion and the second light-blocking portion are configured to a defined shape.

25. The electronic apparatus of claim 16, further comprising one or more of the first pixel,
wherein the light-blocking part is configured to cover a surface of the display panel and comprises one or more openings.

26. The electronic apparatus of claim 19, further comprising a black signal provider circuit configured to provide a black signal to the fourth pixel, and comprising a black switch configured to control the black signal,
wherein the display panel is configured to operate in a first mode, or in a second mode different from the first mode.

27. The electronic apparatus of claim 26, wherein the black signal provider circuit is configured to provide the black signal to the fourth pixel.
